(19) United States
(12) Patent Application Publication
(10) Pub. No.: US 2026/0177929 A1
(43) Pub. Date: Jun. 25, 2026

(54) OPTICAL PROXIMITY CORRECTION METHOD AND SEMICONDUCTOR FABRICATION METHOD USING THE SAME

(71) Applicant: Samsung Electronics Co., Ltd., Suwon-si (KR)

(72) Inventors: Dongyeul LEE, Suwon-si (KR); Kyoungyoon PARK, Suwon-si (KR); Useong KIM, Suwon-si (KR); Yangwoo HEO, Suwon-si (KR); Kyoil KOO, Suwon-si (KR)

(73) Assignee: Samsung Electronics Co., Ltd., Suwon-si (KR)

(21) Appl. No.: 19/257,775

(22) Filed: Jul. 2, 2025

(30) Foreign Application Priority Data
Dec. 19, 2024 (KR) 10-2024-0191745

(51) Int. Cl. G03F 7/00; G03F 1/36; G03F 7/004; G03F 7/09; H10B 12/00

(52) U.S. Cl. CPC G03F 7/70441; G03F 1/36; G03F 7/0043; G03F 7/094; G03F 7/70508; G03F 7/7065; H10B 12/053

(57) ABSTRACT

Disclosed is a semiconductor fabrication method comprising forming a under layer and a photoresist layer on a substrate, performing an optical proximity correction (OPC) on a layout, and using a photomask manufactured with the corrected layout to form a photoresist pattern on the under layer. The step of performing the OPC comprises generating a first function that comprises a first correction parameter, producing a resist image from the first function, measuring a target error for the resist image, and correcting the first correction parameter into a second correction parameter. The first correction parameter and the second correction parameter comprise a certain number of hydrogen radicals that migrate from the under layer to the photoresist layer.

### CROSS-REFERENCE TO RELATED APPLICATION

This application claims priority under 35 U.S.C § 119 to Korean Patent Application No. 10-2024-0191745 filed on Dec. 19, 2024 in the Korean Intellectual Property Office, the disclosure of which is hereby incorporated by reference in its entirety.

### BACKGROUND

The present inventive concepts relate to semiconductor fabrication methods, and more particularly, to optical proximity correction (OPC) methods and semiconductor fabrication methods using the same.

Semiconductor devices have an important role in the electronic industry because of their small size, multi-functionality, and/or low fabrication cost. Semiconductor devices may encompass semiconductor memory devices storing logic data, semiconductor logic devices processing operations of logic data, and hybrid semiconductor devices having both memory and logic elements. Semiconductor devices have been increasingly desired for high integration with the advanced development of the electronic industry. For example, semiconductor devices have been increasingly desired for high reliability, high speed, and/or multi-functionality. Semiconductor devices are gradually becoming more complicated and more integrated to meet these desired characteristics.

### SUMMARY

Some embodiments of the present inventive concepts provide optical proximity correction (OPC) methods capable of maintaining consistency of optical proximity correction.

Some embodiments of the present inventive concepts provide methods of fabricating a semiconductor device with increased integration and improved reliability.

According to some embodiments of the present inventive concepts, a semiconductor fabrication method may include forming a under layer and a photoresist layer on a substrate; performing an optical proximity correction (OPC) on a layout to generate a corrected layout; and using a photomask manufactured with the corrected layout to form a photoresist pattern on the under layer. The step of performing the OPC may include generating a first function including a first correction parameter; producing a resist image from the first function; measuring a target error for the resist image; and correcting the first correction parameter into a second correction parameter. The first correction parameter and the second correction parameter may include a certain number of hydrogen radicals that migrate from the under layer to the photoresist layer.

According to some embodiments of the present inventive concepts, a semiconductor fabrication method may include forming a under layer and a photoresist layer on a substrate; performing an optical proximity correction (OPC) on a layout to generate a corrected layout; and using a photomask manufactured with the corrected layout to form a photoresist pattern from the photoresist layer. The step of performing the OPC may include generating a first function that comprises a first correction parameter; producing a resist image from the first function; and measuring a target error for the resist image. The step of forming the photoresist pattern may include using the photomask to irradiate light to the photoresist layer. A first portion of the photoresist layer forms a cross-linking therein and condenses by the light. The step of producing the resist image may include calculating a ratio of a volume of the first portion to a volume of the photoresist layer.

According to some embodiments of the present inventive concepts, a semiconductor fabrication method may include performing an optical proximity correction on a layout to generate a corrected layout; manufacturing a photomask with the corrected layout; forming a under layer and a photoresist layer on a substrate; and using the photomask to expose and develop the photoresist layer to form photoresist patterns. The step of performing the OPC may include generating a first function that comprises a first correction parameter and a process parameter; producing a resist image from the first function; measuring a target error for the resist image; and correcting the first correction parameter into a second correction parameter. The photoresist layer may include metal oxide. The process parameter may include a thickness of the under layer.

According to some embodiments of the present inventive concepts, a semiconductor fabrication device may include processing circuitry configured to determine a layout, and perform an optical proximity correction (OPC) on the layout to generate a corrected layout, including generating a first function including a first correction parameter, producing a resist image from the first function, measuring a target error for the resist image, and correcting the first correction parameter into a second correction parameter.

According to some embodiments of the present inventive concepts, the processing circuitry is further configured to store the corrected layout to generate a photomask and form a photoresist pattern.

### BRIEF DESCRIPTION OF DRAWINGS

FIG. 1 illustrates a block diagram showing a computer system for semiconductor design according to some embodiments of the present inventive concepts.

FIG. 2 illustrates a flow chart showing a method of designing and fabricating a semiconductor device according to some embodiments of the present inventive concepts.

FIG. 3 illustrates a conceptual diagram showing a photolithography system that uses a photomask manufactured according to some embodiments of the present inventive concepts.

FIGS. 4 and 5 illustrate flow charts showing detailed steps of optical proximity correction according to some embodiments of the present inventive concepts.

FIG. 6 illustrates a conceptual diagram showing a photolithography process in which a photomask is used to print a circuit pattern on a substrate.

FIG. 7 illustrates a cross-sectional view showing a photolithography process according to some embodiments of the present inventive concepts.

FIG. 8 illustrates an enlarged view showing section M of FIG. 7.

FIG. 9 illustrates a graph showing the degree of cross-linking between a first part and a second part according to some embodiments of the present inventive concepts.

FIG. 10 illustrates a graph showing the degree of cross-linking between a first part and a second part according to a comparative example of the present inventive concepts.

FIG. 11 illustrates a graph showing migration of hydrogen radicals between a photoresist layer and a under layer according to some embodiments of the present inventive concepts.

FIG. 12 illustrates an enlarged view showing section M of FIG. 7 according to some embodiments of the present inventive concepts.

FIG. 13 illustrates a conceptual diagram showing a target error according to some embodiments of the present inventive concepts.

FIG. 14 illustrates a conceptual diagram showing that a photomask is used to form photoresist patterns on a substrate.

FIGS. 15, 17, 19, 21, 23, 25, 27, and 29 illustrate plan views showing a semiconductor fabrication method according to some embodiments of the present inventive concepts.

FIGS. 16A, 18A, 20A, 22A, 24A, 26A, 28A, and 30A illustrate cross-sectional views taken along line A-A′ of FIGS. 15, 17, 19, 21, 23, 25, 27, and 29, respectively.

FIGS. 16B, 18B, 20B, 22B, 24B, 26B, 28B, and 30B illustrate cross-sectional views taken along line B-B′ of FIGS. 15, 17, 19, 21, 23, 25, 27, and 29, respectively.

FIGS. 16C, 18C, 20C, 22C, 24C, 26C, 28C, and 30C illustrate cross-sectional views taken along line C-C′ of FIGS. 15, 17, 19, 21, 23, 25, 27, and 29, respectively.

FIGS. 16D, 18D, 20D, 22D, 24D, 26D, 28D, and 30D illustrate cross-sectional views taken along line D-D′ of FIGS. 15, 17, 19, 21, 23, 25, 27, and 29, respectively.

### DETAILED DESCRIPTION OF EMBODIMENTS

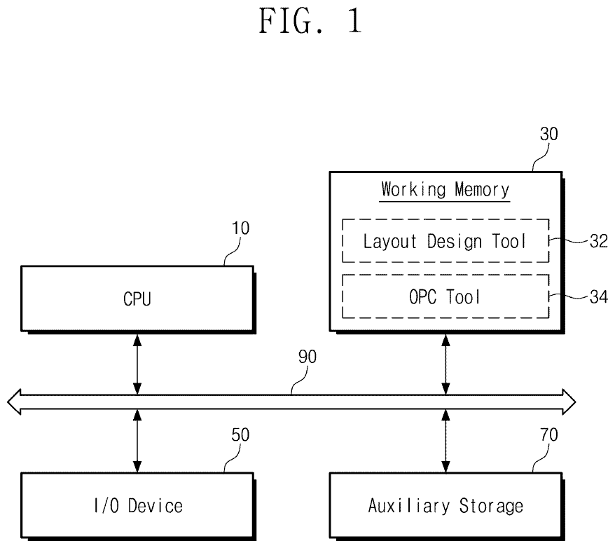

FIG. 1 illustrates a block diagram showing a computer system for semiconductor design according to some embodiments of the present inventive concepts. Referring to FIG. 1, a computer system may include a central processing unit (CPU) 10, a working memory 30, an input/output device 50, and an auxiliary storage 70. The computer system may be provided as a dedicated device for designing a layout of the present inventive concepts. The computer system may be configured to drive various design and verification simulation programs.

The CPU 10 may control the computer system to execute software (e.g., application programs, operating system, and device drivers). The CPU 10 may process an operating system loaded in the working memory 30. The CPU 10 may execute various application programs driven based on the operating system (OS). For example, the CPU 10 may process a layout design tool 32 and/or an optical proximity correction (OPC) tool 34 that are loaded in the working memory 30.

The operating system (OS) or application programs may be loaded in the working memory 30. When the computer system is booted up, based on booting sequence, an operating system image (not shown) stored in the auxiliary storage 70 may be loaded to the working memory 30. Overall input/output operations of the computer system may be supported by the operating system (OS). The working memory 30 may be loaded with the application programs that are selected by a user or provided for a basic service. The layout design tool 32 and/or the OPC tool 34 may be loaded from the auxiliary storage 70 to the working memory 30.

The layout design tool 32 may include a bias function by which specific layout patterns are changed in shapes and positions defined by a design rule. In addition, the layout design tool 32 may perform a design rule check (DRC) under the changed bias data condition. The OPC tool 34 may perform optical proximity correction (OPC) on layout data output from the layout design tool 32. The working memory 30 may be either a volatile memory such as static random access memory (SRAM) and dynamic random access memory (DRAM) or a nonvolatile memory such as phase change random access memory (PRAM), magnetic random access memory (MRAM), resistance random access memory (ReRAM), ferroelectric random access memory (FRAM), and NOR Flash memory.

The input/output device 50 may control user input/output operations of user interfaces. For example, the input/output device 50 may include a keyboard and/or a monitor, allowing a designer to input relevant information. The user may use the input/output device 50 to receive information about a semiconductor region or data paths requiring adjusted operating characteristics. The input/output device 50 may display a progress status or a process result of the OPC tool 34.

The auxiliary storage 70 may serve as a storage medium for the computer system. The auxiliary storage 70 may store the application programs, the operating system image, and various data. The auxiliary storage 70 may be provided in the form of one of memory cards (e.g., MMC, eMMC, SD, and Micro SD) and a hard disk drive (HDD). The auxiliary storage 70 may include a NAND Flash memory having large memory capacity. Alternatively, the auxiliary storage 70 may include a NOR Flash memory or a next-generation volatile memory such as PRAM, MRAM, ReRAM, and FRAM.

A system interconnector 90 may be provided to serve as a system bus for providing a network in the computer system. The CPU 10, the working memory 30, the input/output device 50, and the auxiliary storage 70 may be electrically connected through the system interconnector 90 and may exchange data with each other. The system interconnector 90 is not limited to the above description, and may further include intermediary means for efficient management.

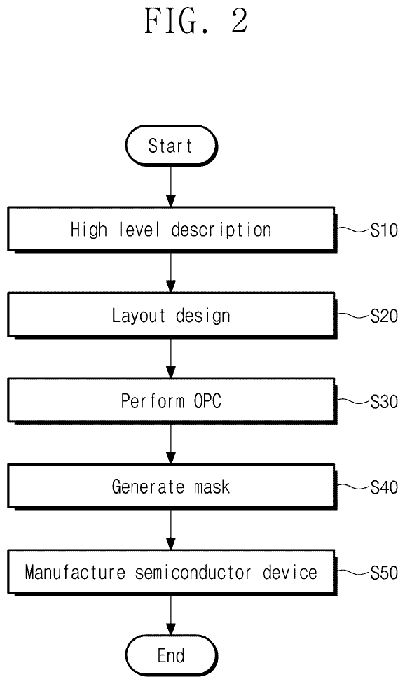

FIG. 2 illustrates a flow chart showing a method of designing and fabricating a semiconductor device according to some embodiments of the present inventive concepts.

Referring to FIG. 2, a high-level design of a semiconductor integrated circuit may be performed using the computer system discussed with reference to FIG. 1 (S10). The high-level design may mean that an integrated circuit corresponding to a design target is described with a high-level language of a hardware description language. For example, the high-level language such as C language may be used in the high level design. A register transfer level (RTL) coding or simulation may be used to express in detail circuits designed by the high-level design. In addition, codes created by the resist transfer level coding may be converted into a netlist, which netlist may be synthesized to describe an entire semiconductor device. The synthesized schematic circuit may be verified by a simulation tool, and an adjustment process may be performed based on the verified result.

A layout design may be performed to implement on a silicon substrate a semiconductor integrated circuit that is logically completed (S20). For example, the layout design step may be performed based on the schematic circuit synthesized in the high-level design step or the netlist corresponding to the schematic circuit. The layout design step may include a routing step that places and connects various standard cells provided from a cell library, based on a prescribed design rule.

A cell library for the layout design may include information about operation, speed, and power consumption of the standard cell. The cell library for representing a layout of a specific gate-level circuit as a layout may be defined in the layout design tool. The layout may be prepared to define shapes or dimensions of patterns constituting transistors and metal lines that will be actually formed on a silicon substrate. For example, in order to actually form an inverter circuit on a silicon substrate, it may be beneficial to appropriately place or describe layout patterns such as PMOS, NMOS, N-WELL, gate electrodes, and/or metal lines thereon. For this, for example, a search may be first performed to select a suitable one of inverters predefined in the cell library.

Thereafter, a routing step of connecting the selected and provided standard cells may be performed. Specifically, a routing step may be performed to connect the selected and placed standard cells to their overlying lines. The standard cells may be well-designedly connected to each other through the routing step. A series of these steps may be automatically or manually performed in the layout design tool. A step of placing and routing the standard cells may be automatically performed by an additional Place & Routing tool.

After the routing step, a verification step may be performed on the layout to check whether any portion of the schematic circuit violates the given design rule. The verification step may include a design rule check (DRC) for verifying whether the layout meets the given design rule, an electrical rule check (ERC) for verifying whether there is an issue of an electrical disconnection in the layout, and a layout vs. schematic (LVS) for verifying whether the layout agrees with the gate-level netlist.

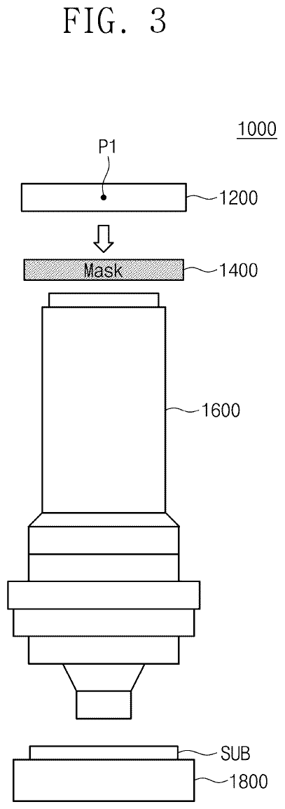

An optical proximity correction (OPC) step may be performed (S30). A photolithography process may be employed to achieve on a silicon substrate the layout patterns obtained by the layout design step. The optical proximity correction process may be a technique for correcting an unintended optical effect that occurs in the photolithography process. For example, the optical proximity correction process may correct an undesirable phenomenon, such as refraction or process side-effects caused by characteristics of light in an exposure process using the layout patterns. When the optical proximity correction step is performed, the designed layout patterns may be slightly changed (or biased) in shapes and positions. The optical proximity correction step will be further discussed in detail with reference to FIGS. 3 to 8.

A photomask may be generated based on the layout changed by the optical proximity correction step (S40). The photomask may generally be manufactured by describing the layout patterns using a chromium layer coated on a glass substrate.

The generated photomask may be used to manufacture a semiconductor device (S50). Various exposure and etching processes may be repeatedly performed in manufacturing the semiconductor device using the photomask. Through these processes discussed above, patterns defined in the layout design may be sequentially formed on a silicon substrate.

FIG. 3 illustrates a conceptual diagram showing a photolithography system that uses a photomask manufactured according to some embodiments of the present inventive concepts. The photolithography system 1000 may include a light source 1200, a photomask 1400, a reduction projection apparatus 1600, and a substrate stage 1800. The photolithography system 1000 may further include components that are not shown in FIG. 3. For example, the photolithography system 1000 may further include a sensor used for measuring height and slope of a surface of a substrate SUB.

The light source 1200 may emit light. The light emitted from the light source 1200 may travel toward the photomask 1400. For example, the light source 1200 and the photomask 1400 may be provided therebetween with a lens to adjust a focus of the light. The light source 1200 may include an extreme ultraviolet (EUV) light source. The light source 1200 may include a single point light source P1, but the present inventive concepts are not limited thereto. In some embodiments, the light source 1200 may include a plurality of point light sources.

The photomask 1400 may include image patterns to print (implement) the designed layout on the substrate SUB. The image patterns may be formed based layout patterns obtained from the layout design and the optical proximity correction that are discussed above. The image patterns may be defined by a transparent region and an opaque region. The transparent region may be formed by etching a metal layer (e.g., a chromium layer) on the photomask 1400. The transparent region may be transparent to the light emitted from the light source 1200. In contrast, the opaque region may block the light without allowing the light to pass therethrough.

The reduction projection apparatus 1600 may receive light that passes through the transparent region of the photomask 1400. The reduction projection apparatus 1600 may match layout patterns, which will be printed on the substrate SUB, with the image patterns of the photomask 1400. The substrate SUB may be irradiated with the light that passes through the reduction projection apparatus 1600. Therefore, the substrate SUB may be printed thereon with patterns that correspond to the image patterns of the photomask 1400.

The substrate stage 1800 may support the substrate SUB. For example, the substrate SUB may include a silicon wafer. The reduction projection apparatus 1600 may include an aperture. The aperture may be used to raise a depth of focus of an ultraviolet ray emitted from the light source 1200. For example, the aperture may include a dipole aperture or a quadruple aperture. The reduction projection apparatus 1600 may further include a lens to adjust a focus of light.

An increase in integration of semiconductor devices may relatively decrease a distance between the image patterns of the photomask 1400. Such “proximity” may cause to induce interference and diffraction of light, and a distorted pattern may be printed on the substrate SUB. When distorted patterns are printed on the substrate SUB, designed circuits may abnormally operate.

A resolution enhancement technology may be used to prevent or reduce a pattern distortion. Optical proximity correction (see S30 of FIG. 2) may be an example of the resolution enhancement technology. According to the optical proximity correction, it may be possible to predict the degree of distortion such as interference and diffraction of light. Based on predicted results, a designed layout may be changed (biased). Based on the changed layout, image patterns may be formed on the photomask 1400, and desired patterns may then be printed on the substrate SUB.

A layout of a semiconductor device may include a plurality of layers. For example, the optical proximity correction may be performed to adjust a layout of a single layer. To be specific, the optical proximity correction may be independently performed on each of the plurality of layers. The plurality of layers may be sequentially implemented through semiconductor processes on a substrate to form a semiconductor device. For example, a semiconductor device may include a plurality of stacked metal layers to achieve a specific circuit.

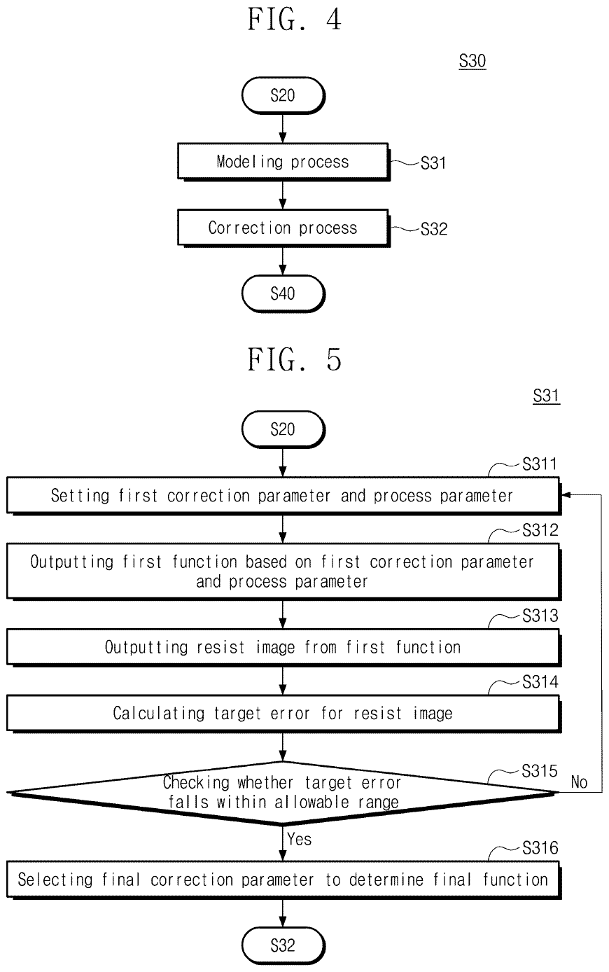

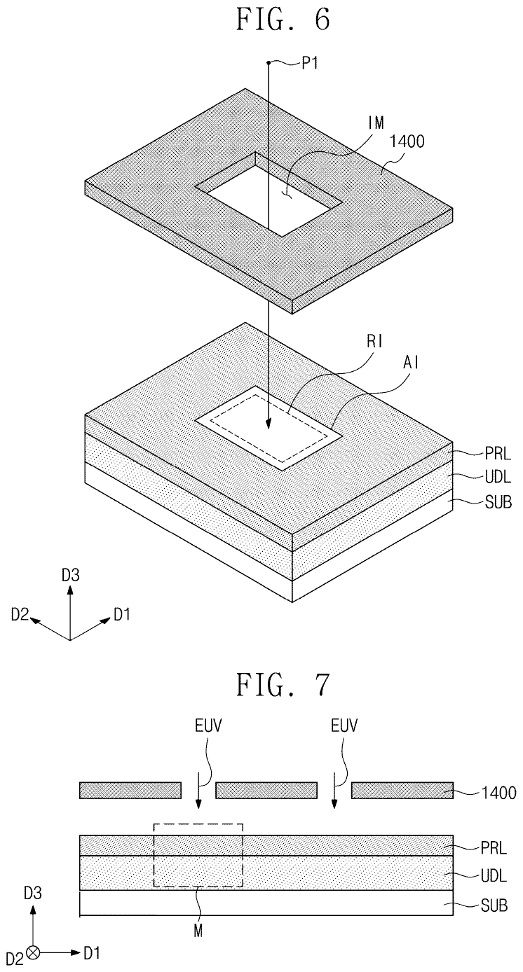

FIGS. 4 and 5 illustrate flow charts showing detailed steps of optical proximity correction according to some embodiments of the present inventive concepts. FIG. 6 illustrates a conceptual diagram showing a photolithography process in which a photomask is used to print a circuit pattern on a substrate.

Referring to FIG. 4, the optical proximity correction (OPC) step may include a modeling process and a correction process. The modeling process may be a task in which optical characteristics and process variations are considered to execute mathematical modeling for predicting a pattern. For example, the modeling process may be a process for optimizing models of the photomask 1400 and patterns formed thereon in consideration of physicochemical phenomena that occur during an actual process procedure in the photomask 1400 and a photoresist layer (see PRL of FIG. 6).

The correction process may be a task in which, based on the modeling result, the photomask 1400 is corrected to minimize a pattern distortion. For example, the correction process may be a process in which a layout of the photomask 1400 is corrected, the corrected layout is simulated again to check the result, and this process is repeatedly performed for optimization.

Referring to FIG. 5, the optical proximity correction (OPC) step according to the present inventive concepts may be the modeling process. A first correction parameter and a process parameter may be set or established as an initial value (S311). The first correction parameter may include a plurality of coefficients which will be discussed below, and the process parameter may include a thickness of a under layer (see UDL of FIG. 6).

Based on the set first correction parameter and the set process parameter, a first function may be output (S312). A resist image (see RI of FIG. 6) may be output from the first function (S313). The resist image RI may refer to patterns actually implanted on a photoresist layer PRL. A subsequently described target error EPE between an aerial image (see AI of FIG. 6) and the resist image RI may be calculated (S314), and it may be checked whether the target error EPE falls within an allowable (or, alternatively, target, desirable, or determined) range (S315). When the target error EPE does not fall within the allowable range, the first correction parameter may be corrected with a second correction parameter, and thus the first function may be corrected. The second correction parameter may be corrected until the target error EPE falls within the allowable range. A final correction parameter may be set or established to determine a final function (S316).

Referring to FIG. 6, the point light source P1 of the light source 1200 depicted in FIG. 3 may emit light toward the photomask 1400. The emitted light may pass through a transparent region of an image pattern IM, and then may travel toward a negative photoresist on the substrate SUB (an exposure process). On the negative photoresist, a region on which the light is irradiated may remain, and a region on which no light is irradiated may be removed (a development process). Therefore, a resist image RI corresponding to the image pattern IM may be printed on the substrate SUB.

The photomask 1400 may be provided on the substrate SUB. The photomask 1400 may include the image pattern IM on which is reflected a layout generated through the layout design step S20 discussed above with reference to FIG. 2. A shape of the designed layout is an example provided for understanding the present inventive concepts, and the present inventive concepts are not limited thereto. The designed layout may be provided as an initially designed layout.

The substrate SUB may be provided beneath the photomask 1400. A under layer UDL and a photoresist layer PRL may be sequentially provided on the substrate SUB. The substrate SUB and the under layer UDL may be provided therebetween with additional layers (e.g., a layer including oxide and/or SiON). For example, an oxide layer may further be provided between the substrate SUB and the under layer UDL.

An aerial image AI that appears on the photoresist layer PRL may be a pattern intended to be implemented on the photoresist layer PRL by light passing through the transparent region of the image pattern IM. In contrast, the resist image RI may be a pattern actually formed on the photoresist layer PRL by light causing a physicochemical reaction on the photoresist layer PRL. An error may occur between the aerial image AI and the resist image RI. This may be caused by the fact that light is irradiated to the photoresist layer PRL to cause a physicochemical reaction of the photoresist layer PRL.

According to the present inventive concepts, before the photomask 1400 is actually corrected, the modeling process may be employed to reduce the error occurring between the aerial image AI and the resist image RI. For example, characteristics (e.g., thickness) of the photoresist layer PRL and the under layer UDL may be considered to calculate a correlation between the aerial image AI and the resist image RI. In the present inventive concepts, a pattern intended to be formed on the photoresist layer PRL and a pattern actually formed after light reacts with the photoresist layer PRL may be output, and then an error between these patterns may be repeatedly calculated and corrected to derive a relational expression between the patterns.

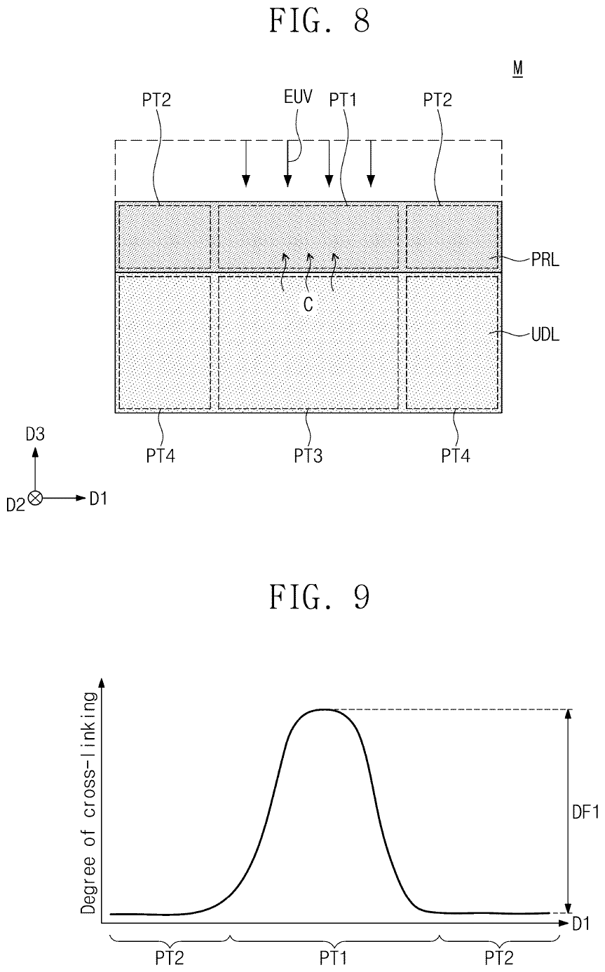

FIG. 7 illustrates a cross-sectional view showing a photolithography process according to some embodiments of the present inventive concepts. FIG. 8 illustrates an enlarged view showing section M of FIG. 7. FIG. 9 illustrates a graph showing the degree of cross-linking between a first part and a second part according to some embodiments of the present inventive concepts. With reference to FIGS. 7 to 9, the following will describe in detail a modeling process of the present inventive concepts.

Referring to FIGS. 7 to 9, light EUV may pass through a transparent region of the photomask 1400 to reach the photoresist layer PRL. The photoresist layer PRL may include a first part PT1 and a second part PT2 that are spaced apart from each other in a first direction D1. The first part PT1 may be a portion where the light EUV reaches after passing through the transparent region of the photomask 1400. The second part PT2 may be a portion where the light EUV is not irradiated by the photomask 1400.

The under layer UDL may include a third part PT3 and a fourth part PT4. The third part PT3 may be provided beneath the first part PT1, and the light EUV is able to reach the third part PT3. The fourth part PT4 may be provided beneath the second part PT2, and the photomask 1400 blocks the light EUV from reaching the fourth part PT4.

A first function may be used to predict the resist image RI formed by a physicochemical reaction of the photoresist layer PRL, which physicochemical reaction is created by the light EUV. The first function will be discussed below.

The light EUV may be irradiated to the photoresist layer PRL and the under layer UDL. The photoresist layer PRL may be a metal oxide resist (MOR). The MOR may be an inorganic material containing metal oxide, where a chemical change occurs due to the light EUV, such that a specific region to be selectively dissolved or retained. The photoresist layer PRL may include metal oxide, such as at least one selected from hafnium (Hf), zirconium (Zr), and tin (Sn).

The light EUV may be an extreme ultraviolet (EUV). In this description, the extreme ultraviolet (EUV) may refer to an ultraviolet ray having a wavelength of about or exactly 4 nm to about or exactly 124 nm, narrowly about or exactly 4 nm to about or exactly 20 nm, and more narrowly about or exactly 13.5 nm. The extreme ultraviolet (EUV) may indicate light whose energy is in the range of about or exactly 6.21 eV to about or exactly 124 eV, for example, about or exactly 90 eV to about or exactly 95 eV.

When the photoresist layer PRL receives photon of the light EUV, ligands of metal oxide molecules in the photoresist layer PRL may be separated. For example, when the photoresist layer PRL includes tin (Sn), a ligand of tin (Sn) may be separated as shown in Chemical Formula 1.

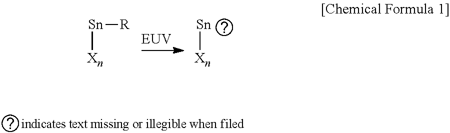

As shown in Chemical Formula 2, the tin (Sn) from which the ligand is separated and a water molecule may react to obtain an OH group. In Chemical Formula 1, X may be metal, and n may be an integer equal to or greater than 1.

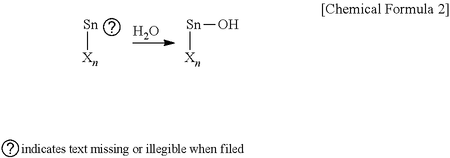

Afterwards, as shown in Chemical Formula 3, molecules obtaining OH groups may be bonded to each other.

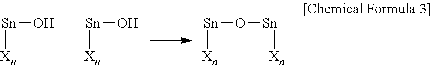

The reactions according to Chemical Formulae 1 to 3 may continuously cascade such that metal oxide molecules may be condensed in a cross-linked state. Except the condensed photoresist layer PRL, a remaining portion may be removed later.

After the irradiation of the light EUV, a bake process may be performed. The bake process may be a process to supply the photoresist layer PRL with a thermal energy. In the bake process, as shown in Chemical Formula 4, a thermal energy may force OH-bound tin (Sn) to lose a ligand. As shown in Chemical Formulae 2 and 3, the molecules of Chemical Formula 4 may obtain OH groups, and the OH-bound molecules may be bonded to each other.

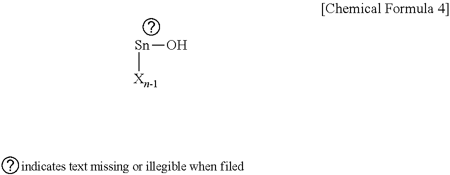

Thus, the cross-linking and the condensation of the photoresist layer PRL may be more accelerated without the light EUV. The reactions occurring in the bake process may be autocatalytic thermolysis.

For example, the irradiation of the light EUV and the bake process may induce the occurrence of two reactions according to Chemical Formulae 6 and 7 in the photoresist layer PRL. Chemical Formula 6 may express the reactions according to Chemical Formulae 1 to 3, and Chemical Formula 7 may express the reaction (e.g., autocatalytic thermolysis) according to Chemical Formula 4.

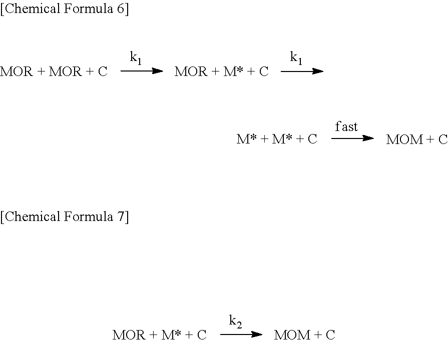

In Chemical Formulae 6 and 7, MOR may be metal oxide, M* may be metal oxide from which a ligand is separated, and MOM may be metal oxides that are bonded to each other. C may be a reaction catalyst, for example, hydrogen. Here, k₁ and k₂ may be reaction rate coefficients, which may be experimentally determined.

A ratio of MOM to the total volume of the photoresist layer PRL may be derived based on Chemical Formulae 6 and 7. For example, a ratio of the condensed photoresist layer PRL caused by the light EUV and the bake process may be derived from the photoresist layer PRL.

For example, F₁ may refer to a state where no ligand of MOR is separated, F₂ may refer to a state where a ligand of MOR is separated, and F₃ may refer to a state where MOM is formed by being bonded together. Thereafter, a chemical reaction rate equation may be used to establish F₁, F₂, and F₃ as concentration functions over time t. The functions may be represented by Mathematical Equations 1 to 3.

$$\frac{{dF}_{1}}{dt} = - ( {k}_{1} + {k}_{c 1} C ) {F}_{1} \qquad [ Mathematical Equation 1 ]$$

$$\frac{{dF}_{2}}{dt} = - ( {k}_{1} + {k}_{c 1} C ) {F}_{1} - ( {k}_{1} + {k}_{2} + {k}_{c 2} C ) {F}_{2} \qquad [ Mathematical Equation 2 ]$$

$$\frac{{dF}_{3}}{dt} = ( {k}_{1} + {k}_{2} + {k}_{c 2} C ) {F}_{2} \qquad [ Mathematical Equation 3 ]$$

In Mathematical Equations 1 to 3, k_{c1} may be a reaction rate coefficient of catalyst C in Chemical Formula 6, and k_{c2} may be a reaction rate coefficient of catalyst C in Chemical Formula 7.

In Mathematical Equations 1 to 3, F₁, F₂, and F₃ may be integrated with respect to time t to show as functions of time t. F₁, F₂, and F₃ may be represented by Mathematical Equations 4 to 6.

$${F}_{1} ( t ) = exp ( - {k}_{1} t ) exp ( - C ) exp ( - \frac{b}{a} ) \qquad [ Mathematical Equation 4 ]$$

$${F}_{2} ( t ) = ( \frac{{k}_{1} + C}{{k}_{2}} ) exp ( - {k}_{1} t ) \{ 1 - exp ( - {k}_{2} t ) \} exp ( - C ) exp ( - \frac{b}{a} ) \qquad [ Mathematical Equation 5 ]$$

$${F}_{3} ( t ) = 1 - {F}_{1} ( t ) - {F}_{2} ( t ) \qquad [ Mathematical Equation 6 ]$$

In Mathematical Equations 5 and 6, a may refer to the number of photons of the light EUV per ligand, and b may refer to the number of ligands per unit volume of the photoresist layer PRL.

In Mathematical Equation 6, F₃(t) may indicate a ratio of MOM to the total volume of the photoresist layer PRL. Therefore, the first function discussed above may be Mathematical Equation 6. The first function may be used to determine a volume of the photoresist layer PRL condensed by the light EUV and an actual pattern formed on the photoresist layer PRL. It may thus be possible to calculate an error between an intended pattern and a pattern that is actually formed with a chemical reaction induced by the photoresist layer PRL.

Referring back to FIG. 8, the catalyst C may be provided from the under layer UDL. For example, the under layer UDL may include a large amount of hydrogen, and the light EUV may create hydrogen radicals in the under layer UDL. The created hydrogen radicals may migrate from the under layer UDL toward the photoresist layer PRL, and may thus be used as a catalyst in a chemical reaction of the photoresist layer PRL.

Referring to FIG. 9, as the under layer UDL provides a hydrogen radical as a catalyst, there may be an increase in the degree of cross-linking of the photoresist layer PRL. This may be caused by the fact that a larger amount of the light EUV is irradiated to the third part PT3 of the under layer UDL than to the fourth part PT4 of the under layer UDL, and thus that a larger amount of hydrogen radicals is created.

Therefore, the first part PT1 of the photoresist layer PRL may have a greater degree of cross-linking and, as a result, a larger volume of condensed portion compared to the second part PT2 of the photoresist layer PRL. This may be caused by the fact that the first part PT1 is provided with a large amount of hydrogen radicals generated in the third part PT3, and that the reaction equations according to Chemical Formulae 1 to 3 proceed actively.

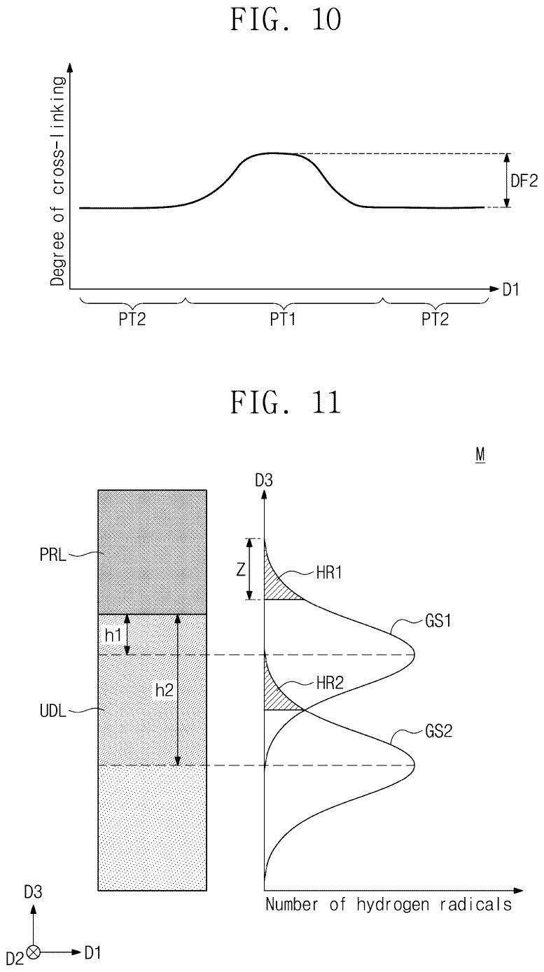

FIG. 10 illustrates a graph showing the degree of cross-linking between a first part and a second part according to a comparative example of the present inventive concepts. FIG. 10 depicts by way of example a graph showing the degree of cross-linking of the photoresist layer PRL when the under layer UDL is not provided.

Referring to FIGS. 9 and 10 in comparison with each other, it may be observed that a difference in the degree of cross-linking between the first part PT1 and the second part PT2 is greater in a case DF1 according to some embodiments of the present inventive concepts than in a case DF2 according to a comparative example of the present inventive concepts. Thus, it may be ascertained that the providing of hydrogen radicals to the photoresist layer PRL is capable of maximizing a difference in the degree of cross-linking between the first part PT1 and the second part PT2 of the photoresist layer PRL. As shown in FIG. 9, an increase in the degree of cross-linking between the first part PT1 and the second part PT2 (e.g., DF1) causes an increase in accuracy and precision in forming the photoresist layer PRL.

FIG. 11 illustrates a graph showing migration of hydrogen radicals between the photoresist layer PRL and the under layer UDL according to some embodiments of the present inventive concepts.

Referring to FIG. 11 and Mathematical Equations 4 to 6, it may be found that an amount C of catalyst provided to the photoresist layer PRL is required to obtain F₃(t). The amount C of catalyst may be substantially the same as a sum of all of hydrogen radicals generated at vertical levels of the under layer UDL. In this case, hydrogen generated at a specific point may perform Gaussian diffusion.

For example, hydrogen generated from a location at a first depth h1 of the under layer UDL may vertically diffuse in a manner identical or similar to a first Gaussian graph GS1 in a graph of FIG. 11. The hydrogen generated at the first depth h1 may diffuse in a form that gradually decreases in upward and downward directions. Likewise, hydrogen generated from a location at a second depth h2 of the under layer UDL may vertically diffuse in a manner identical or similar to a second Gaussian graph GS2.

An amount of hydrogen that diffuses to the photoresist layer PRL may depend on an area of an edge portion that corresponds to a first range Z in the first Gaussian graph GS1. The arbitrary first range Z may be variously changed based on, for example, temperature and/or a thickness and/or material of the under layer UDL.

For example, the migration of hydrogen to the photoresist layer PRL may be in proportion to a ratio of an area HR1 of the graph corresponding to the first range Z to the total area of the first Gaussian graph GS1 at the first depth h1. Likewise, the migration of hydrogen to the photoresist layer PRL may be in proportion to a ratio of an area HR2 of the graph corresponding to a second range to the total area of the second Gaussian graph GS2 at the second depth h2. In summary, at a level of the under layer UDL, only hydrogen which corresponds to a certain ratio of generated hydrogen may migrate to the photoresist layer PRL.

This may be summarized as Mathematical Equation 7.

$$C \approx \{ 1 - exp ( - α H ) \} \qquad [ Mathematical Equation 7 ]$$

In Mathematical Equation 7, C may be an amount of hydrogen migrated to the photoresist layer PRL, α may be a catalyst diffusivity, and H may be a total thickness of the under layer UDL. Referring to FIG. 7, it may be observed that an amount of hydrogen radicals is determined by the thickness of the under layer UDL and the catalyst diffusivity.

Mathematical Equation 7 may be used to obtain an amount of hydrogen radicals provided to the photoresist layer PRL. When this is substituted into Mathematical Equation 6, it may be possible to obtain a volume F₃(t) of the condensed portion of the photoresist layer PRL.

Referring back to Mathematical Equations 4 to 7, a plurality of correction parameters and process parameters may be needed to obtain the volume F₃(t) of the condensed portion of the photoresist layer PRL. The correction parameters may include, for example, k₁ as the reaction rate coefficient in Chemical Formula 6, k₂ as the reaction rate coefficient in Chemical Formula 7, k_{c1} as the reaction rate coefficient of catalyst C in Chemical Formula 6, k_{c2} as the reaction rate coefficient of catalyst C in Chemical Formula 7, and α as the catalyst diffusivity in Mathematical Equation 7. The process parameter may include, for example, the thickness of the under layer UDL.

The correction parameters are input and corrected, whereas the process parameter may be a fixed value unless the thickness of the under layer UDL is changed.

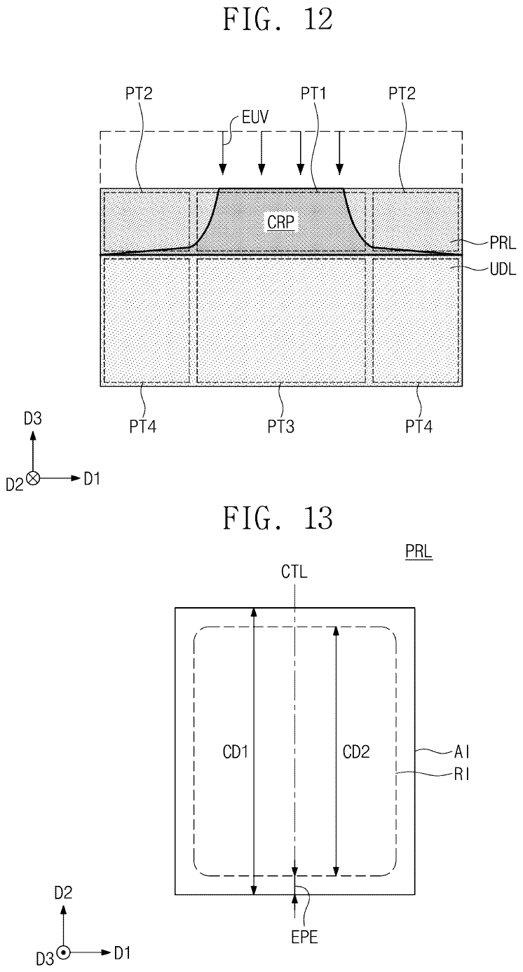

FIG. 12 illustrates an enlarged view showing section M of FIG. 7 according to some embodiments of the present inventive concepts. As shown in FIG. 12, most of the first part PT1 may be condensed to form a condensation pattern CRP. A portion of the second part PT2 may also be condensed to form the condensation pattern CRP, however, the portion of the second part PT2 may have a volume relatively less (and, for example, extremely less) than that of the first part PT1.

FIG. 13 illustrates a conceptual diagram showing a target error according to some embodiments of the present inventive concepts.

After Mathematical Equations 6 and 7 are used to calculate a volume of the condensed portion of the photoresist layer PRL, it may be possible to ascertain an actual pattern formed therethrough. This may be the resist image RI discussed above. A target error EPE may be obtained between the resist image RI and the aerial image AI. The target error EPE may refer to a minimum interval between the resist image RI and the aerial image AI when the resist image RI does not reach the aerial image AI. For example, a central line CTL may be provided which extends in the second direction D2 on the resist image RI and the aerial image AI, and then widths CD1 and CD2 of the resist image RI and the aerial image AI may be measured to acquire a difference between the widths CD1 and CD2, thereby obtaining the target error EPE.

When the target error EPE does not fall within an allowable (or, alternatively, target, desirable, or determined) range, the correction parameters may be corrected while fixing the process parameter (e.g., the thickness of the under layer UDL). The corrected parameters may be substituted into Mathematical Equations 4 to 7 to obtain a corrected value of F₃(t). The target error EPE may be calculated again based on that mentioned above. Referring back to FIG. 5, the correction parameters may be repeatedly corrected until the target error EPE falls within an allowable range.

When the target error EPE falls within an allowable range, the correction parameters may be determined to establish finalized Mathematical Equations 6 and 7, such that the modeling process may continue, and, for example, be completed.

The determined parameters may ensure that the target error EPE remains within an allowable range although the process parameter is changed. For example, after the correction parameters are determined in a state where the thickness of the under layer UDL is about or exactly 10 nm, the target error EPE may fall within an allowable range even when the under layer UDL is changed to have a thickness of about or exactly 20 nm. This may be caused by the fact that, since various correction parameters are minutely adjusted, high accuracy may be maintained even with a variation in thickness of the under layer UDL. Accordingly, the OPC modeling process according to the present inventive concepts may maintain high accuracy and precision even when the thickness of the under layer UDL is changed.

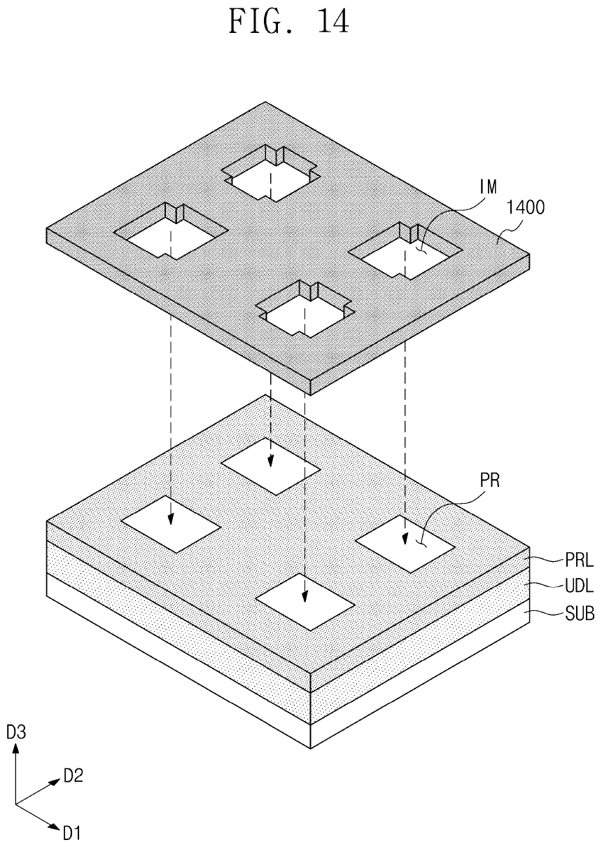

FIG. 14 illustrates a conceptual diagram showing that a photomask is used to form photoresist patterns on a substrate.

Referring to FIG. 14, on the basis of an OPC model optimized based on the determined correction parameters, a correction process may be performed to correct the photomask 1400. The photomask 1400 may thus be corrected. The light EUV may pass through the transparent region of the corrected photomask 1400 to reach the photoresist layer PRL. A region where the light EUV is irradiated to the photoresist layer PRL may be converted into a photoresist pattern PRP.

In the modeling process of the OPC method according to the present inventive concepts, a chemical reaction of a metal oxide resist (MOR) material may be used to obtain a model reflected with characteristics of the photoresist layer PRL and the under layer UDL. Chemical equations and Mathematical Equations according to the present inventive concepts may include correction parameters, and the correction parameters may be corrected until a target error satisfies an allowable range.

In the present inventive concepts, the light EUV may cause chemical reactions of the photoresist layer PRL and the under layer UDL to predict a pattern formed on the photoresist layer PRL. Therefore, accuracy and precision may be improved compared to a case where no modeling process is performed. In addition, the correction parameters may be adapted, and for example, minutely corrected to maintain consistency of OPC and also to improve an OPC method of MOR materials based on the use of the light EUV.

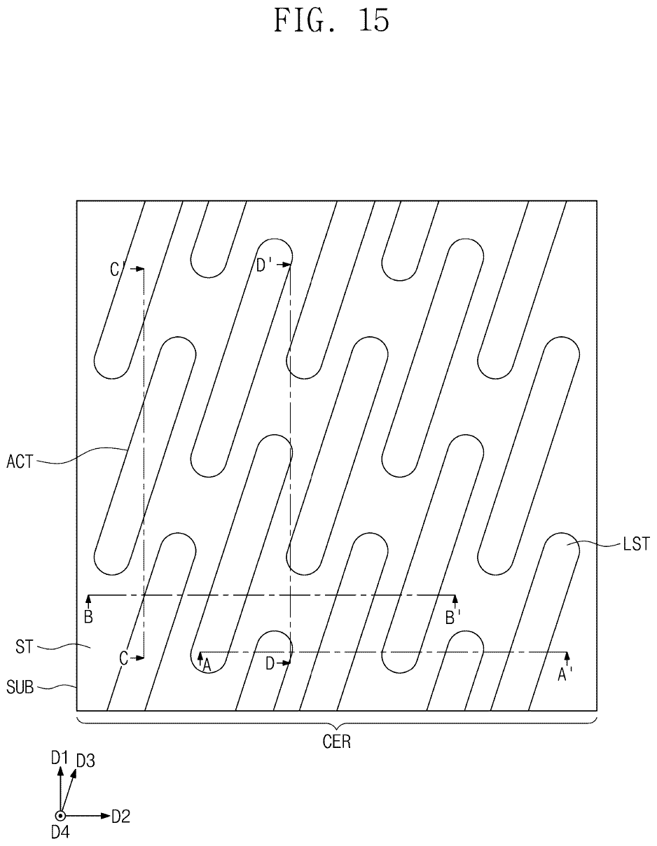

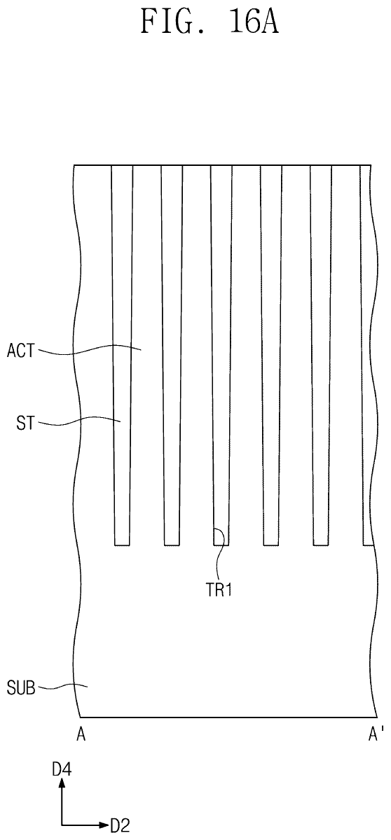

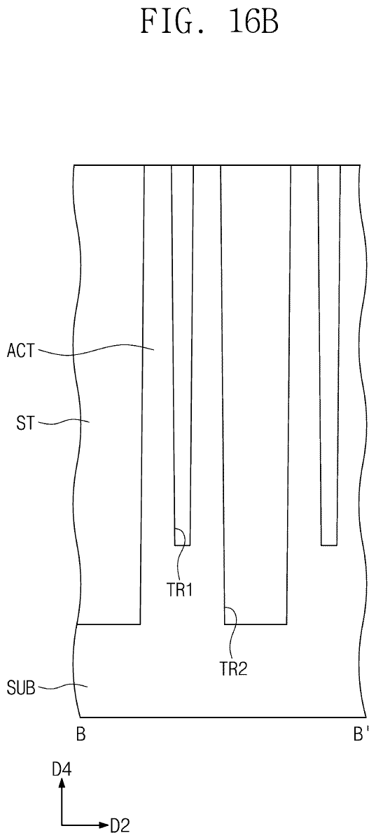

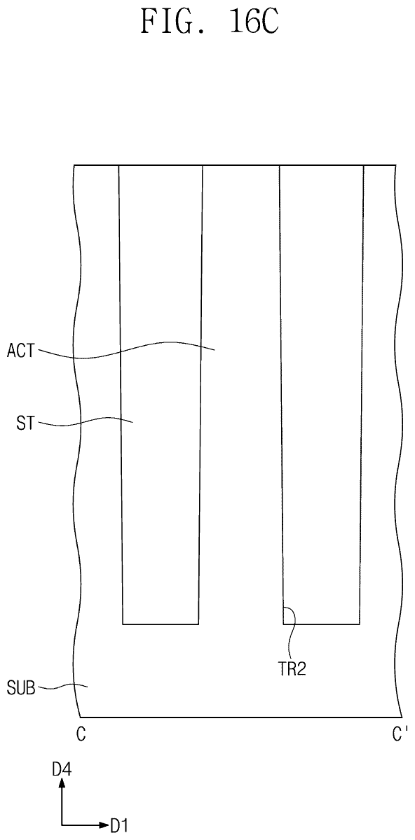

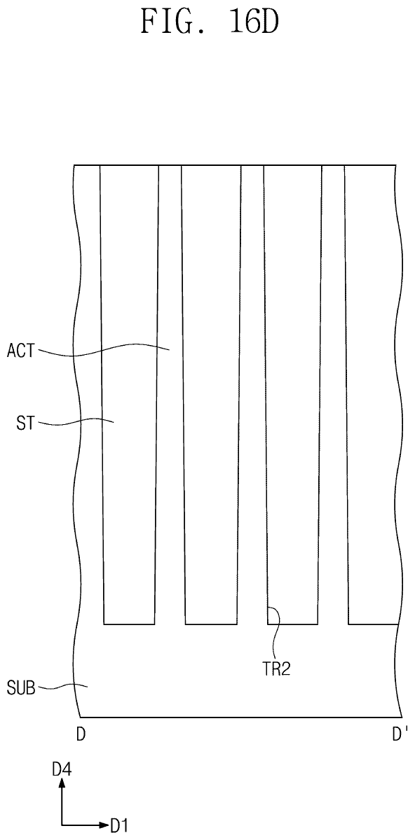

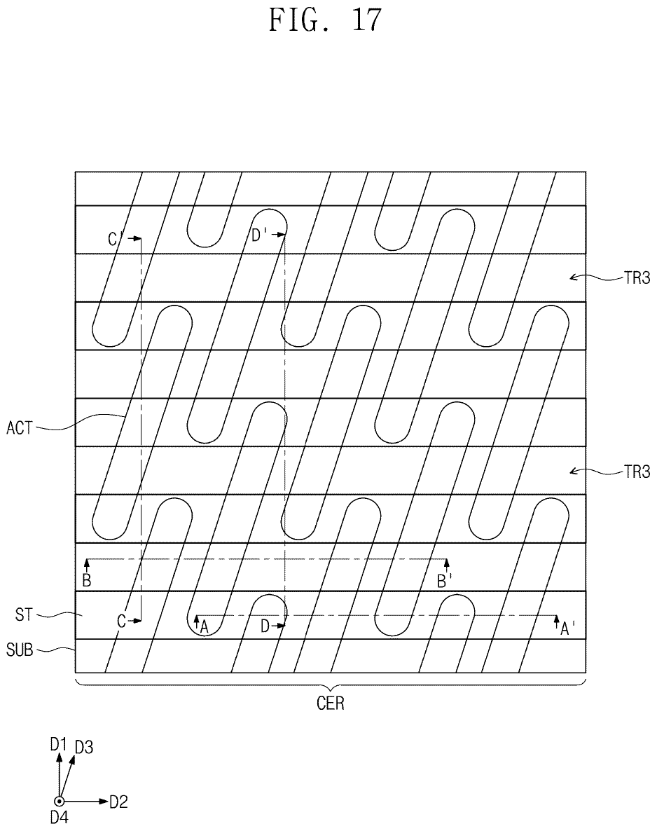

FIGS. 15, 17, 19, 23, 25, 21, 27, and 29 are plan views for explaining a method of fabricating a semiconductor device according to exemplary embodiments of the present inventive concept. FIGS. 16A, 18A, 20A, 22A, 24A, 26A, 28A, and 30A illustrate cross-sectional views taken along line A-A′ of FIGS. 15, 17, 19, 21, 23, 25, 27, and 29, respectively. FIGS. 16B, 18B, 20B, 22B, 24B, 26B, 28B, and 30B illustrate cross-sectional views taken along line B-B′ of FIGS. 15, 17, 19, 21, 23, 25, 27, and 29, respectively. FIGS. 16C, 18C, 20C, 22C, 24C, 26C, 28C, and 30C illustrate cross-sectional views taken along line C-C′ of FIGS. 15, 17, 19, 21, 23, 25, 27, and 29, respectively. FIGS. 16D, 18D, 20D, 22D, 24D, 26D, 28D, and 30D illustrate cross-sectional views taken along line D-D′ of FIGS. 15, 17, 19, 21, 23, 25, 27, and 29, respectively.

Referring to FIGS. 15 and 16A to 16D, an upper portion of a substrate SUB may be patterned to form active patterns ACT. Each of the active patterns ACT may extend in a third direction D3 parallel to a top surface of the substrate SUB. The active patterns ACT may be two-dimensionally arranged along a first direction D1 and a second direction D2. The active patterns ACT may be spaced apart from each other in the third direction D3.

A photolithograph process may be used to achieve the active patterns ACT. A photomask used in the photolithography process for achieving the active patterns ACT may be manufactured through an OPC method according to the present inventive concepts discussed above with reference to FIGS. 5 to 14.

According to some embodiments of the present inventive concepts, an extreme ultraviolet (EUV) lithography process may be adopted as a patterning process for the formation of the active patterns ACT. The EUV lithography process may include exposure and development processes that use an extreme ultraviolet (EUV) radiation irradiated to a photoresist layer. For example, the photoresist layer may be an inorganic photoresist that contains an inorganic material, such as tin oxide.

The photoresist layer may be formed relatively thin. The photoresist layer exposed to the EUV may undergo a development process to form photoresist patterns. When viewed in plan, the photoresist patterns may have a linear shape that extends in one direction, an island shape, a zigzag shape, a honeycomb shape, and/or a circular shape, but the present inventive concepts are not limited to a particular example.

The photoresist patterns may be used as an etching mask to pattern one or more mask layers that are stacked below the photoresist patterns, and thus mask patterns may be formed. The mask patterns may be used as an etching mask to pattern a target layer to form desired patterns on a wafer.

For example, about or exactly 45 nm or less (e.g., about or exactly 45 nm to about or exactly 1 nm, or about or exactly 40 nm to about or exactly 10 nm) may be given as a minimum pitch between the active patterns ACT achieved by the EUV lithography process according to some example embodiments. For example, the EUV lithography process may be performed in which only one photomask is enough to accomplish active patterns ACT that are, for example, more elaborate and more delicate. That is, more precise active patterns ACT, among other features, may be more reliably produced using the EUV lithography process according to some example embodiments.

First and second trenches TR1 and TR2 may be defined between the active patterns ACT. The first trench TR1 may be defined between a pair of active patterns ACT that are adjacent to each other in the second direction D2. The second trench TR2 may be defined between a pair of active patterns ACT that are adjacent to each other in the third direction D3.

A device isolation layer ST may be formed to fill the first and second trenches TR1 and TR2. The device isolation layer ST may be formed to completely fill the first and second trenches TR1 and TR2 and to cover the active patterns ACT. A planarization process may be performed on the device isolation layer ST until top surfaces of the active patterns ACT are exposed.

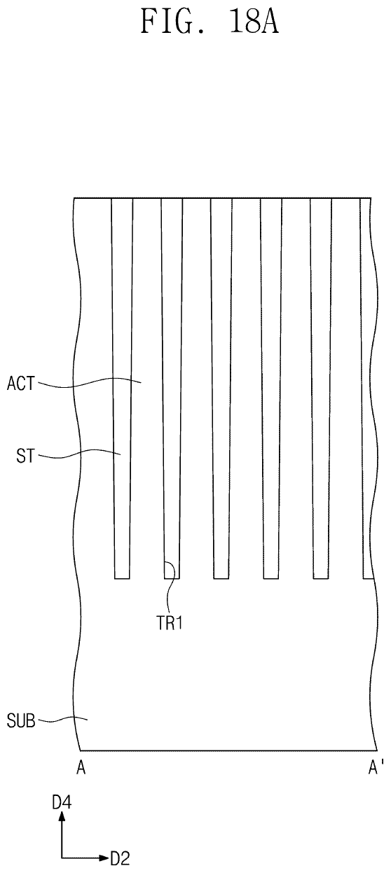

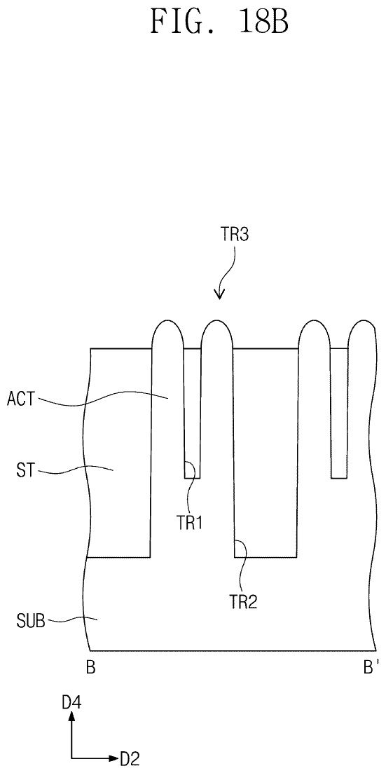

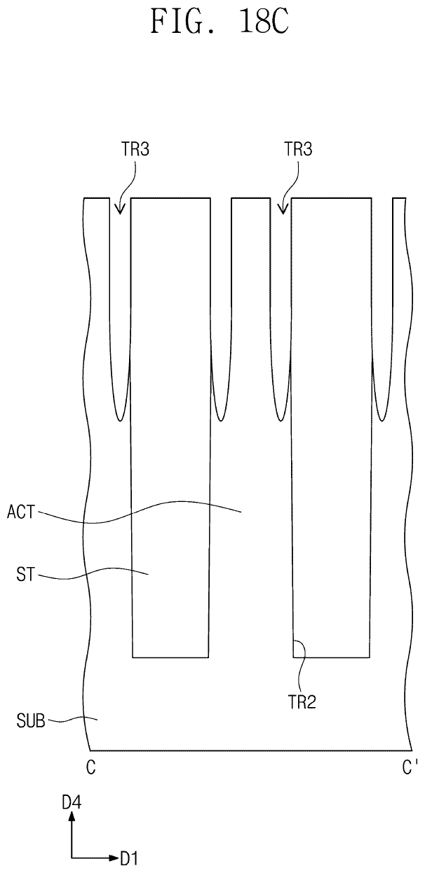

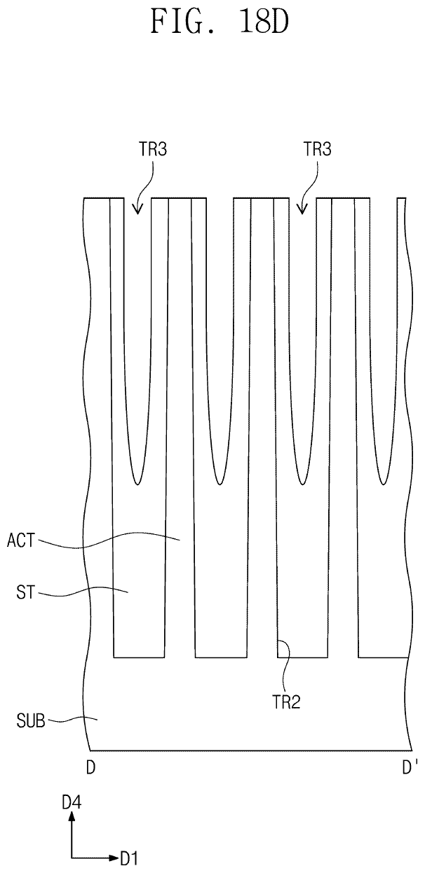

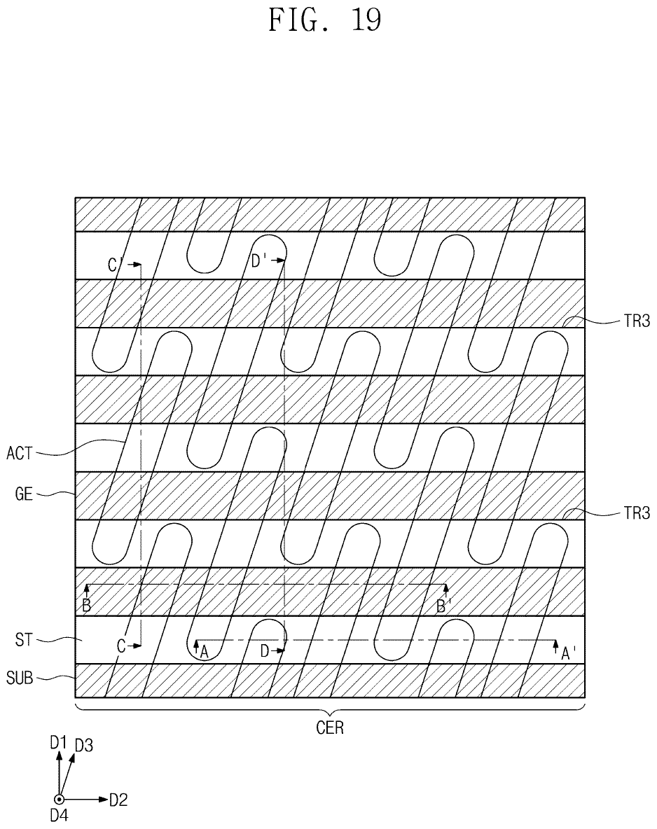

Referring to FIGS. 17 and 18A to 18D, the active patterns ACT and the device isolation layer ST may be patterned to form third trenches TR3. When viewed in plan, each of the third trenches TR3 may have a linear shape that extends in the second direction D2.

The formation of the third trenches TR3 may include forming a hardmask pattern that has openings, and then using the hardmask pattern as an etching mask to etch the exposed active patterns ACT and the device isolation layer ST. The third trench TR3 may be formed shallower than the first trench TR1.

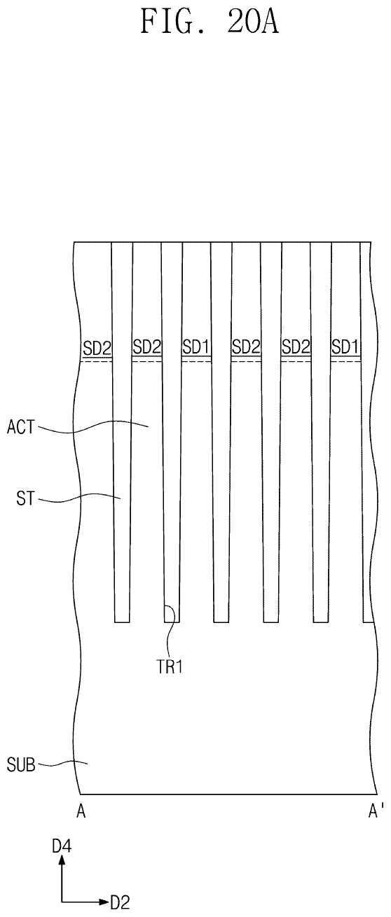

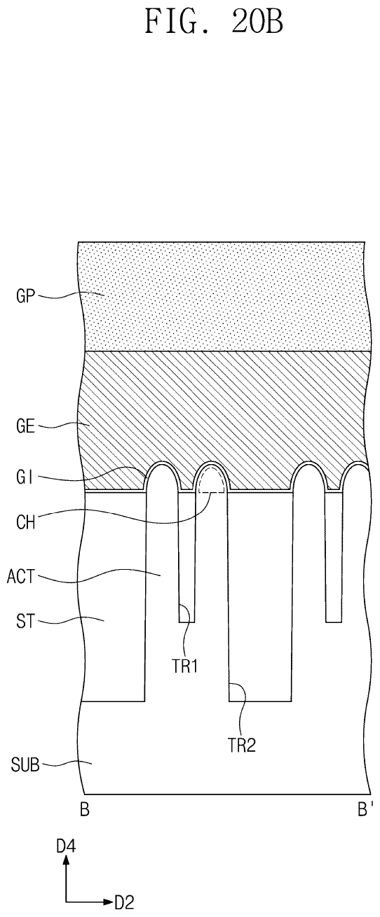

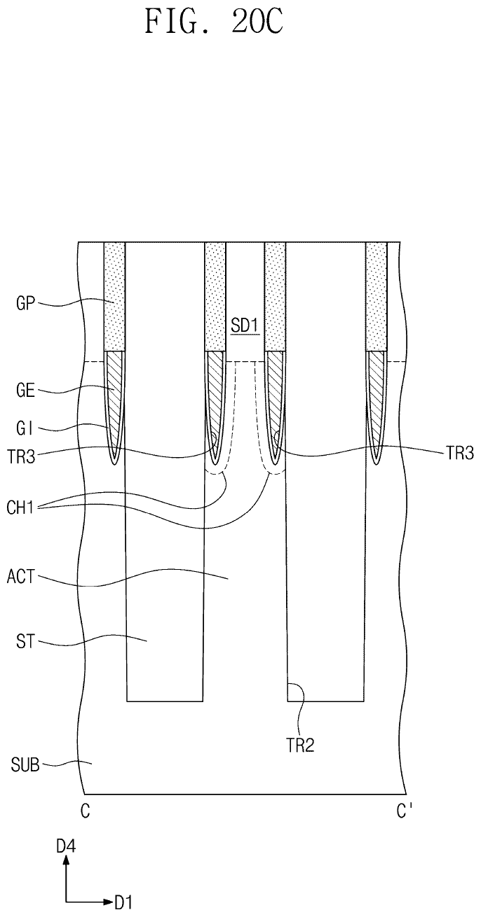

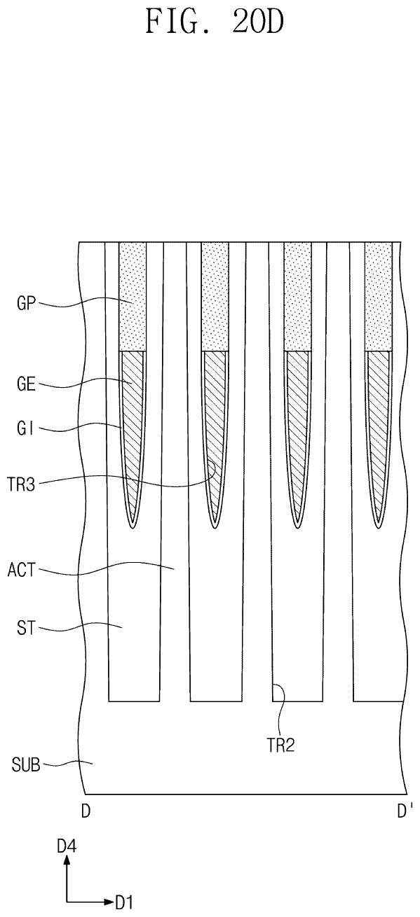

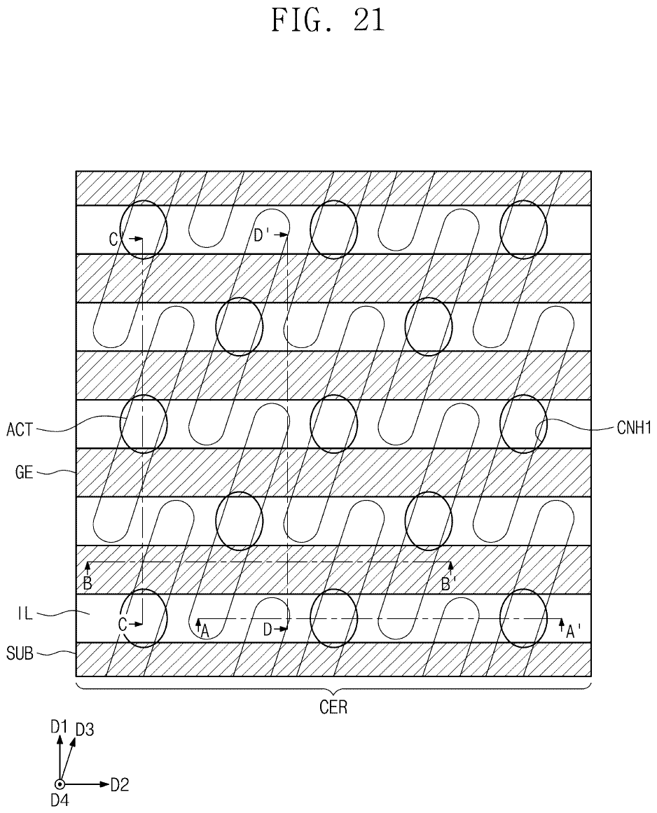

Referring to FIGS. 19 and 20A to 20D, a gate dielectric layer GI, a gate electrode GE, and a gate capping layer GP may be sequentially formed in each of the third trenches TR3. For example, the gate dielectric layer GI may be conformally formed in the third trench TR3. The gate dielectric layer GI may include one or more of a silicon oxide layer, a silicon nitride layer, a silicon oxynitride layer, and a high-k dielectric material.

A conductive layer filling the third trench TR3 may be formed on the gate dielectric layer GI, forming the gate electrode GE. The conductive layer may include one or more of metal and conductive metal nitride.

The gate dielectric layer GI and the gate electrode GE may be recessed, and then the gate capping layer GP may be formed on the recessed gate electrode GE. A top surface of the gate capping layer GP may be coplanar with that of the active pattern ACT.

The active patterns ACT may undergo an ion implantation process to form a first source/drain region SD1 and a pair of second source/drain regions SD2 on an upper portion of the active pattern ACT. The pair of second source/drain regions SD2 may be spaced apart in the third direction D3 from each other across the first source/drain region SD1. For example, the first and second source/drain regions SD1 and SD2 may be doped with the same impurity.

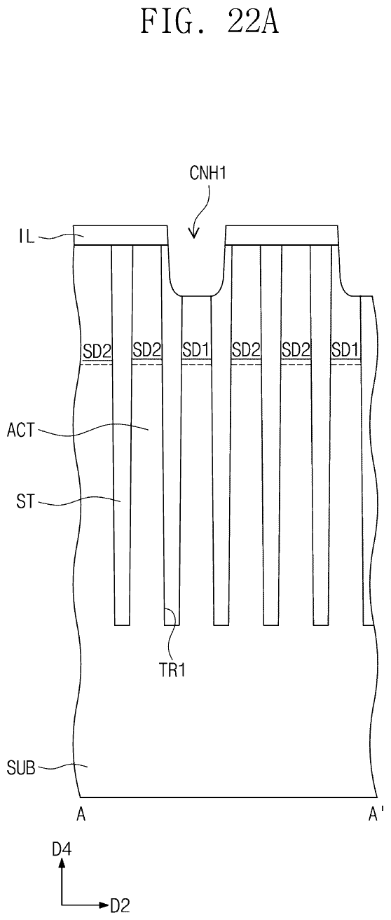

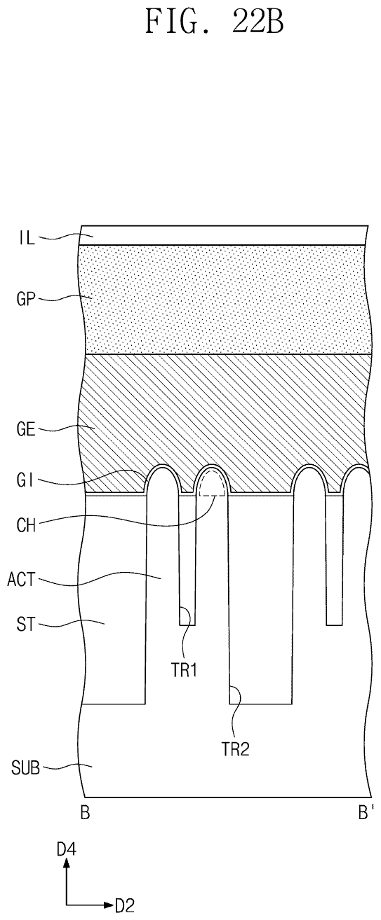

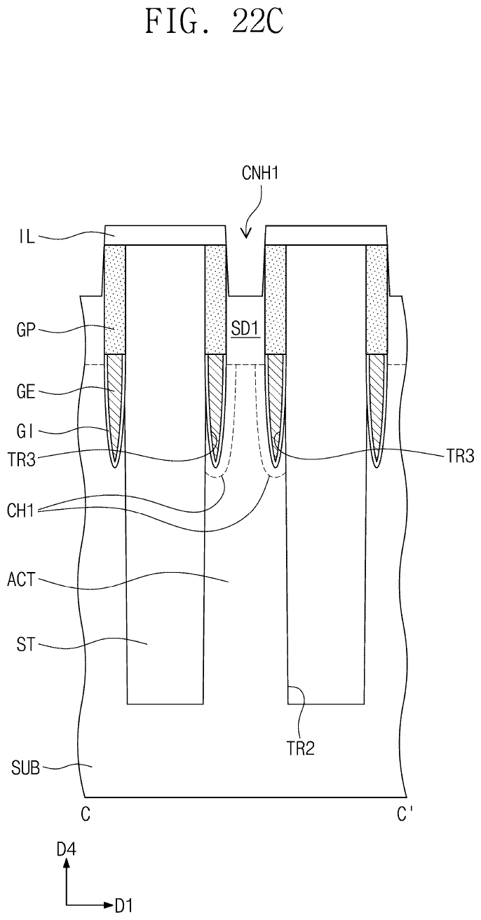

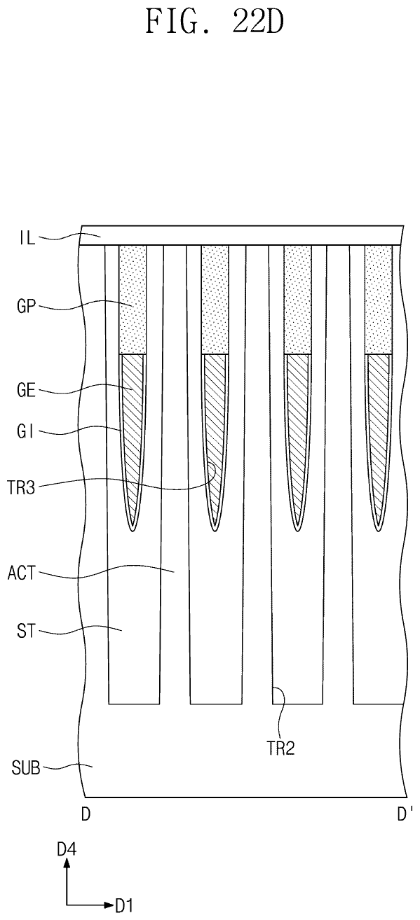

A channel region CH may be defined on the active pattern ACT positioned below the gate electrode GE. When viewed in plan, the channel region CH may be interposed between the first source/drain region SD1 and the second source/drain region SD2. The gate electrode GE may be provided on a top surface and opposite sidewalls of the channel region CH (see FIG. 22B).

Referring to FIGS. 21 and 22A to 22D, a dielectric layer IL may be formed on a front surface of the substrate SUB. For example, the dielectric layer IL may have a multi-layered structure in which a silicon oxide layer and a silicon oxynitride layer are stacked. The dielectric layer IL may be patterned to form first contact holes CNH1 that correspondingly expose the first source/drain regions SD1 of the active patterns ACT. When the first contact hole CNH1 is formed, an upper portion of the first source/drain region SD1 may be recessed. When the first contact hole CNH1 is formed, the device isolation layer ST may be recessed at its upper portion around the first source/drain region SD1.

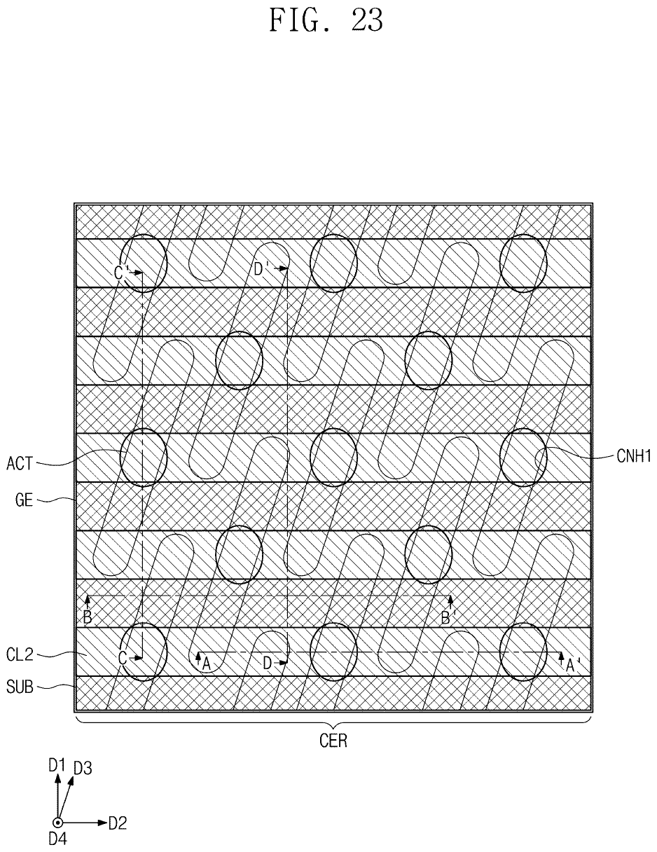

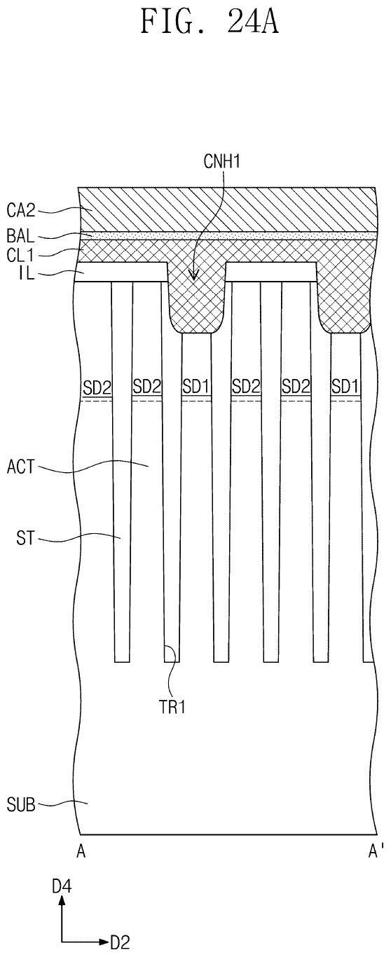

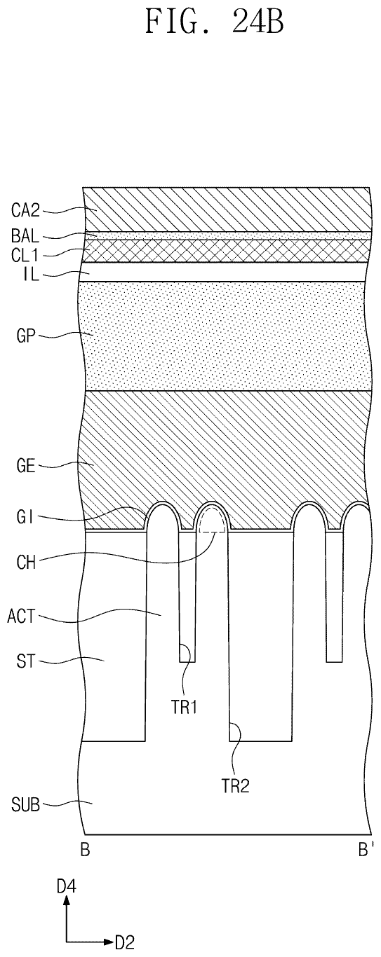

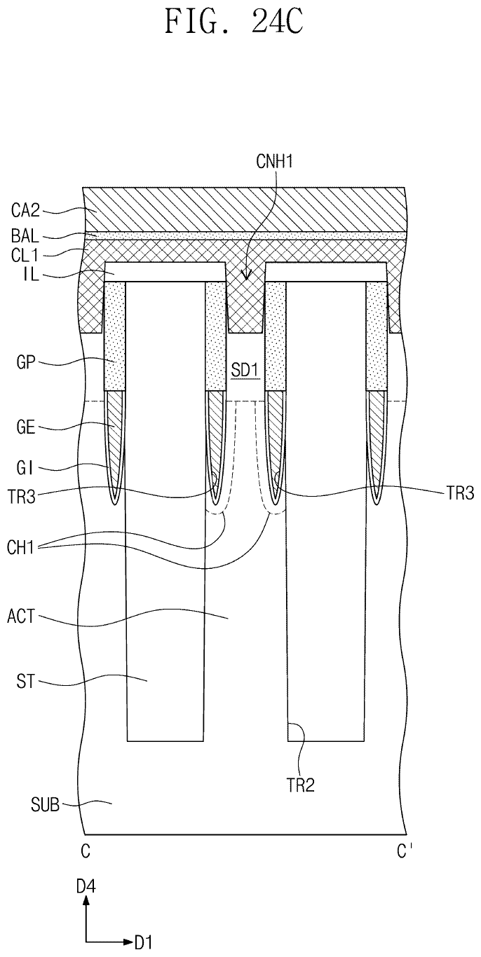

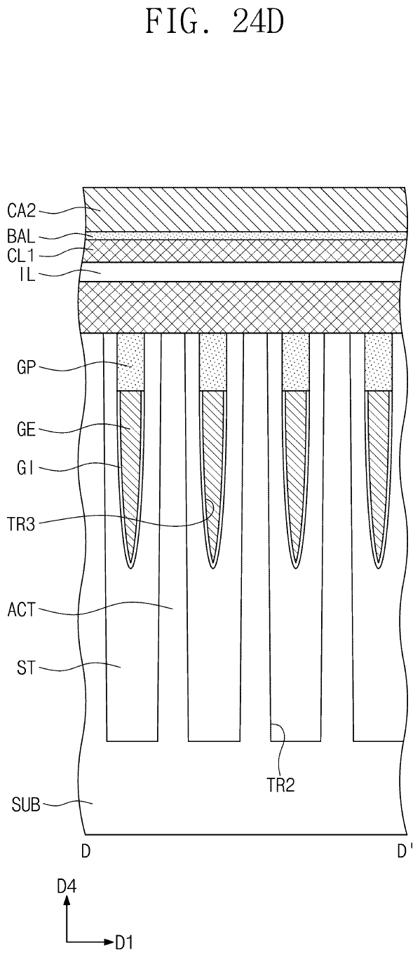

Referring to FIGS. 23 and 24A to 24D, a first conductive layer CL1, a barrier layer BAL, and a second conductive layer CL2 may be sequentially formed on the dielectric layer IL. The first conductive layer CL1 may fill the first contact holes CNH1. For example, the first conductive layer CL1 may be in contact with the first source/drain regions SD1 of the active patterns ACT. The dielectric layer IL may vertically separate the first conductive layer CL1 from the second source/drain regions SD2 of the active patterns ACT. The first conductive layer CL1 may include a doped semiconductor material.

The barrier layer BAL may be formed to lie between the first conductive layer CL1 and the second conductive layer CL2. The barrier layer BAL may include conductive metal nitride. The second conductive layer CL2 may include a metallic material. The barrier layer BAL may suppress the first conductive layer CL1 from receiving a metallic material diffused from the second conductive layer CL2.

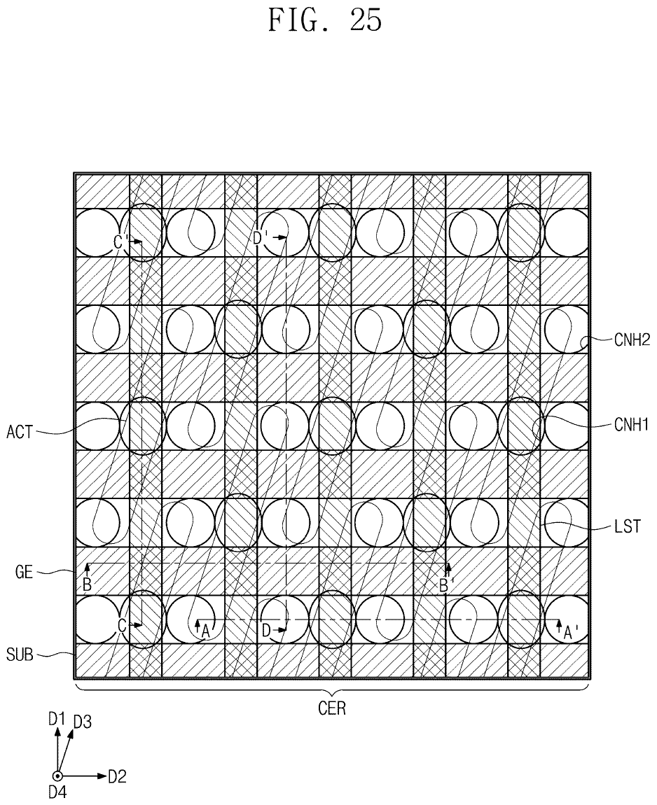

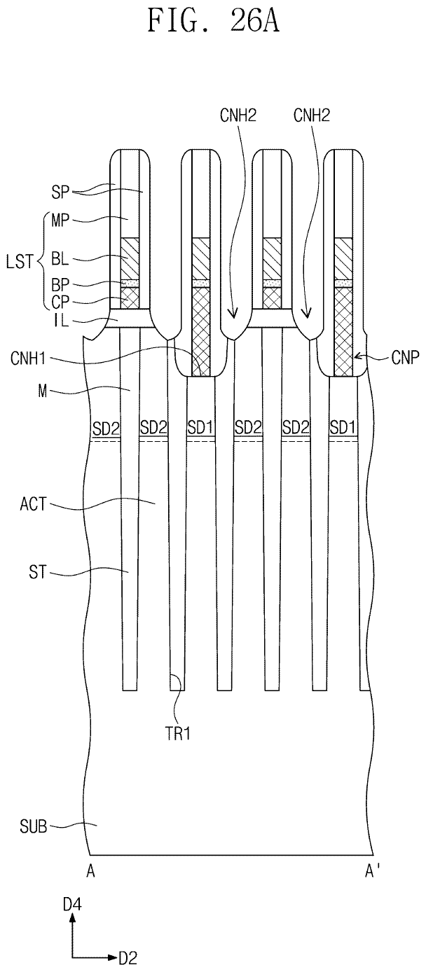

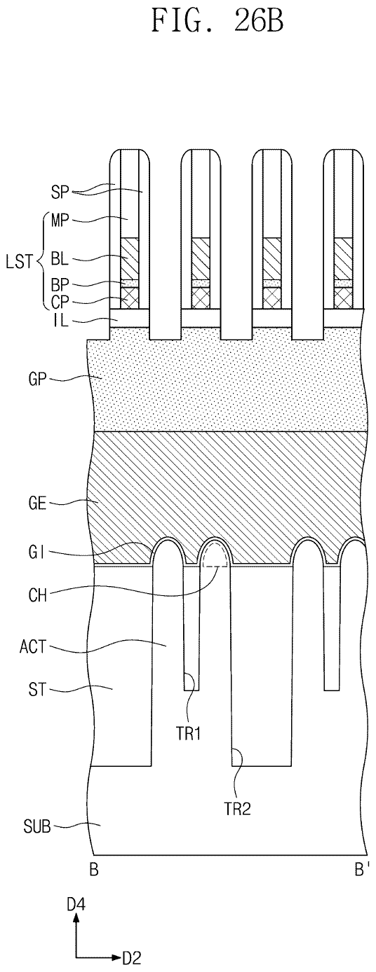

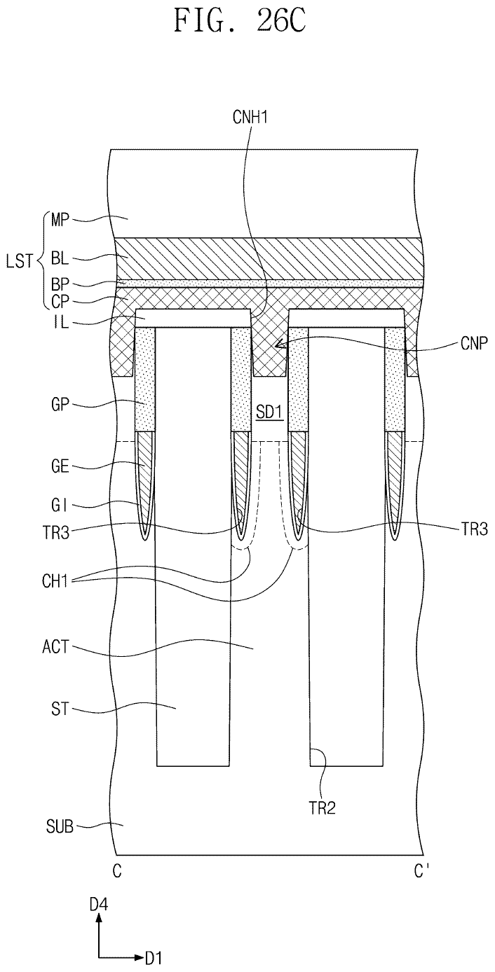

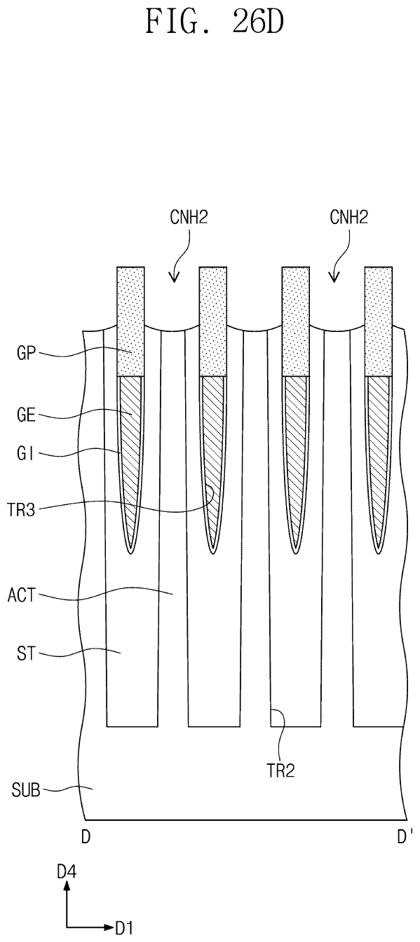

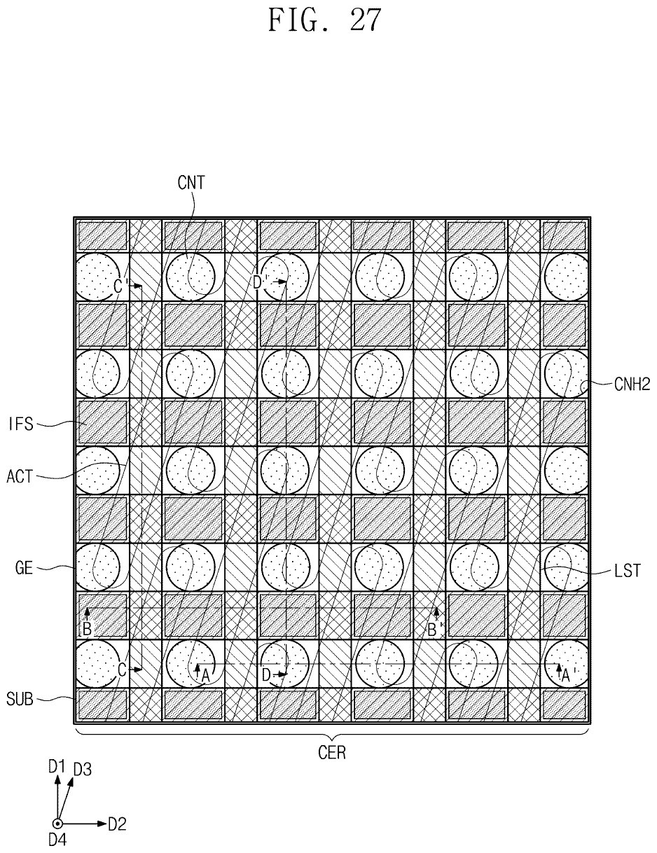

Referring to FIGS. 25 and 26A to 26D, line structures LST may be formed to extend in parallel to each other in the first direction D1 on the dielectric layer IL. The line structures LST may be arranged along the second direction D2.

For example, mask patterns MP may be formed on the second conductive layer CL2. The mask patterns MP may be formed to have their linear shapes that extend in the first direction D1. For example, the mask patterns MP may include a silicon nitride layer and/or a silicon oxynitride layer.

The mask patterns MP may be used as an etching mask to sequentially etch the second conductive layer CL2, the barrier layer BAL, and the first conductive layer CL1 to form a bit line BL, a barrier pattern BP, and a conductive pattern CP, respectively. The mask pattern MP, the bit line BL, the barrier pattern BP, and the conductive pattern CP may vertically overlap each other. The mask pattern MP, the bit line BL, the barrier pattern BP, and the conductive pattern CP may constitute the line structure LST. When viewed in plan, the bit lines BL may extend while intersecting the gate electrodes GE.

The conductive pattern CP may include contact parts CNP that correspondingly fill the first contact holes CNH1. The conductive pattern CP may be connected through the contact part CNP to the first source/drain region SD1. For example, the bit line BL may be electrically connected through the conductive pattern CP to the first source/drain region SD1.

A pair of spacers SP may be formed on opposite sidewalls of each of the line structures LST. The formation of the spacers SP may include conformally forming a spacer layer on the front surface of the substrate SUB and anisotropically etching the spacer layer.

The spacers SP and the mask patterns MP may be used as an etching mask to perform an etching process on the front surface of the substrate SUB, thereby forming second contact holes CNH2 that correspondingly expose the second source/drain regions SD2. For example, the second contact hole CNH2 may penetrate the dielectric layer IL and downwardly extend from the top surface of the substrate SUB. When the second contact hole CNH2 is formed, the second source/drain region SD2 may be recessed at its upper portion. When the second contact hole CNH2 is formed, the device isolation layer ST may be recessed at its upper portion around the second source/drain region SD2.

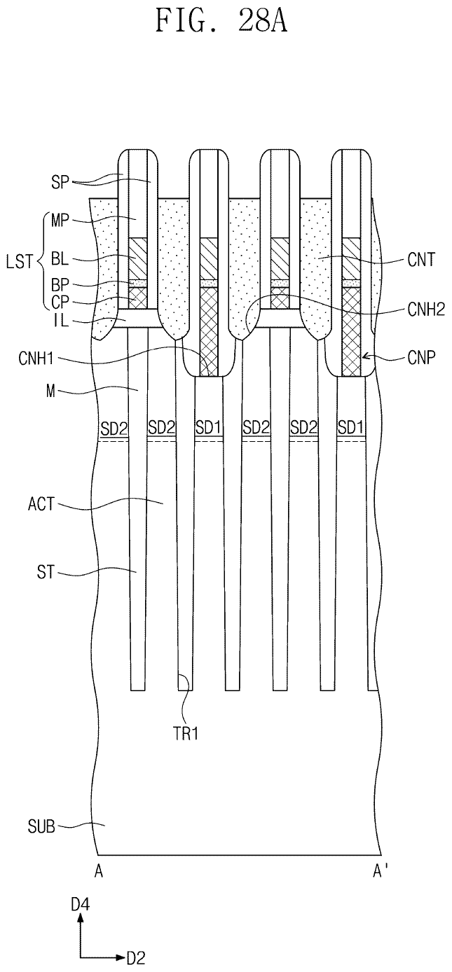

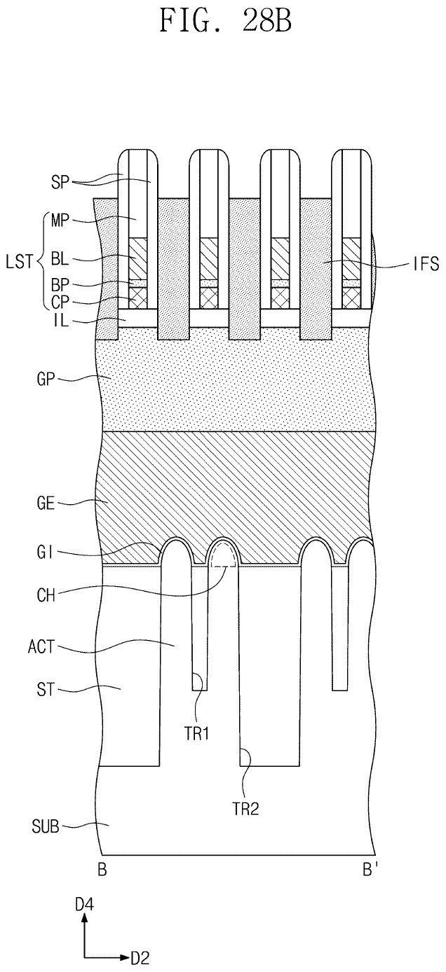

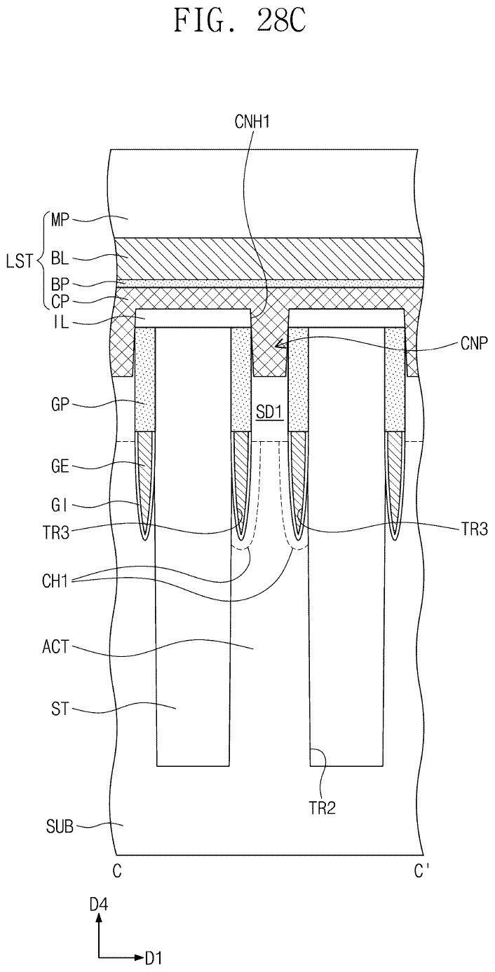

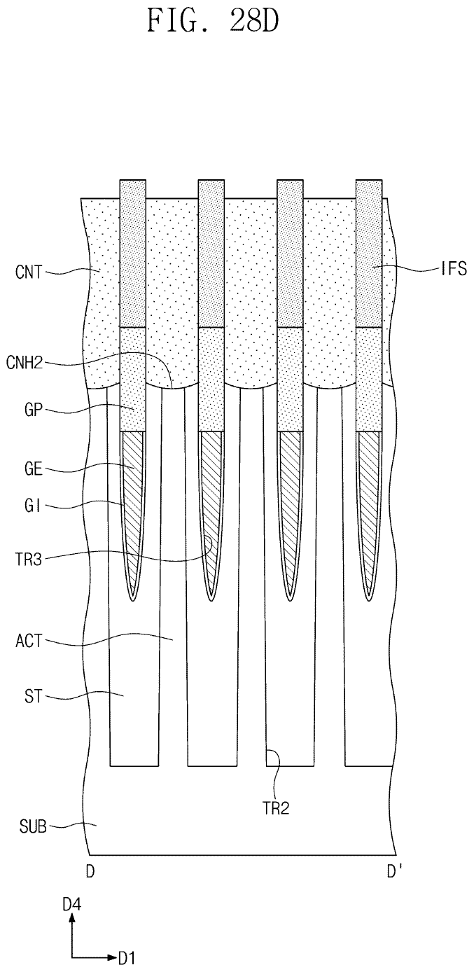

Referring to FIGS. 27 and 28A to 28D, a plurality of dielectric fences IFS may be formed on the gate capping layer GP. The dielectric fences IFS may not overlap but expose the second contact holes CNH2.

The second contact holes CNH2 may be filled with a conductive material to form contacts CNT in corresponding second contact holes CNH2. The contacts CNT may be connected to the second source/drain regions SD2. For example, the conductive material may be formed on the front surface of the substrate SUB, and then the conductive material may be recessed to have a top surface lower than those of the dielectric fences IFS. The dielectric fences IFS may divide the conductive material into pieces, and thus the contacts CNT may be correspondingly formed in the second contact holes CNH2. The contacts CNT and the dielectric fences IFS may be alternately arranged along the first direction D1.

The conductive material that fills the second contact holes CNH2 may be a doped semiconductor material. A doped semiconductor may fill the second contact holes CNH2, and then it may be possible for impurities to diffuse from the doped semiconductor toward the second source/drain regions SD2.

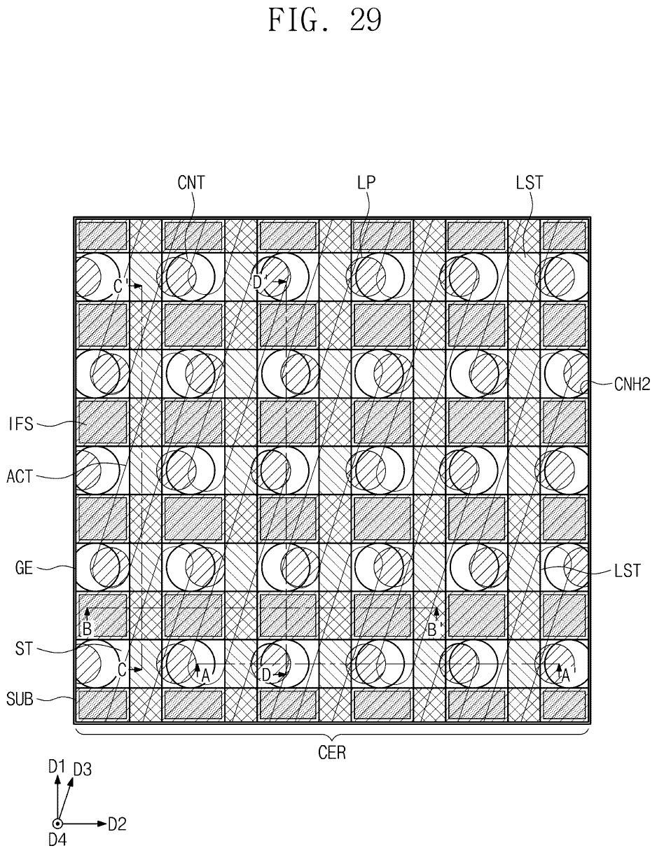

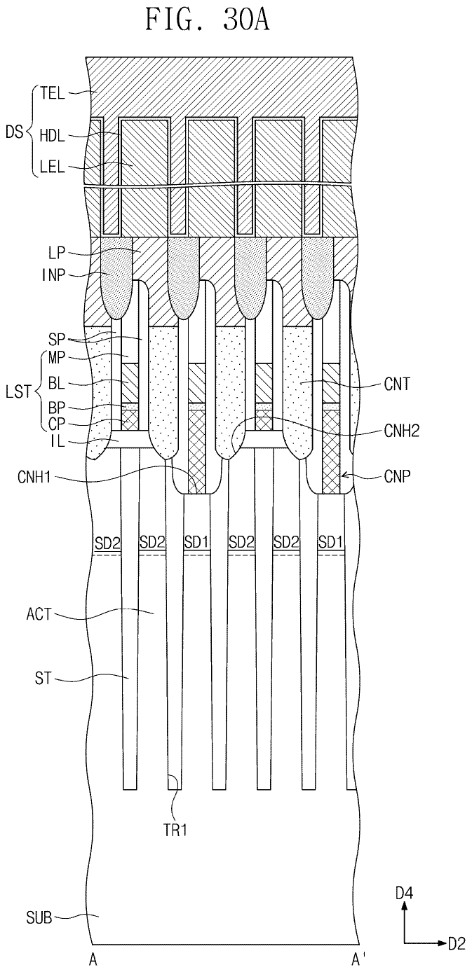

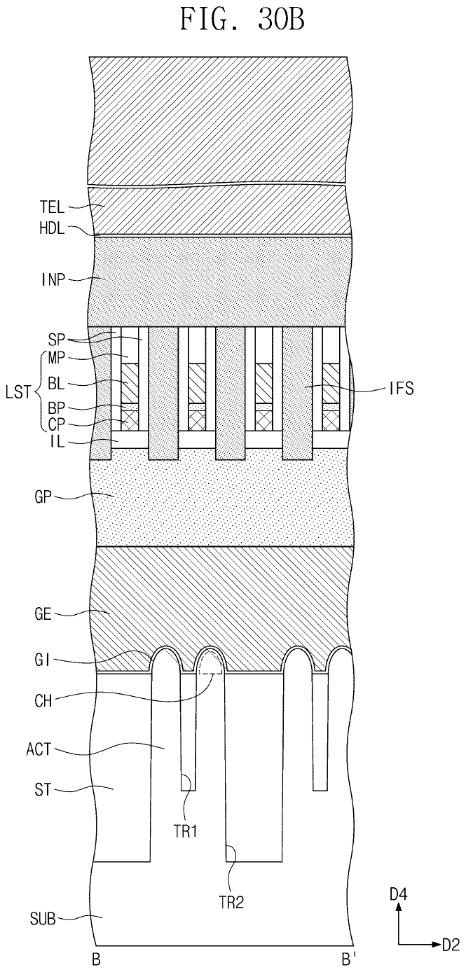

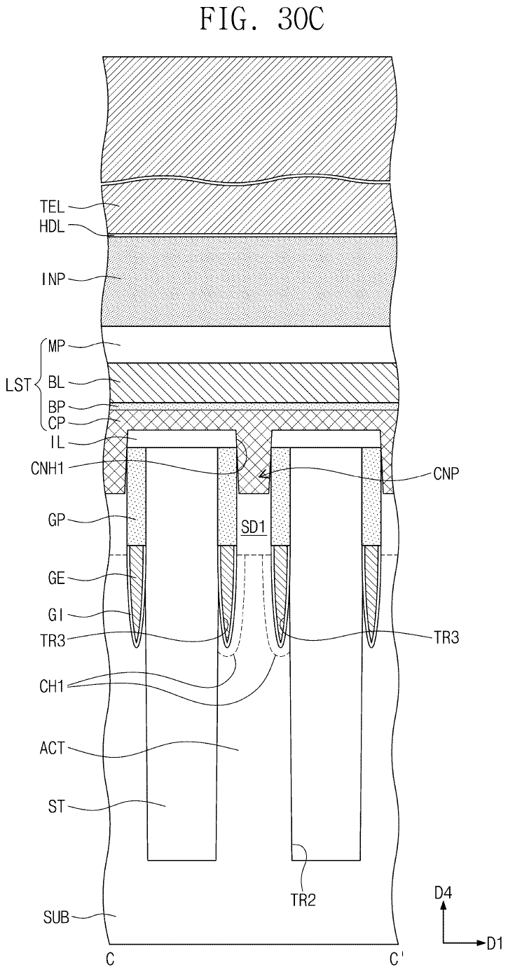

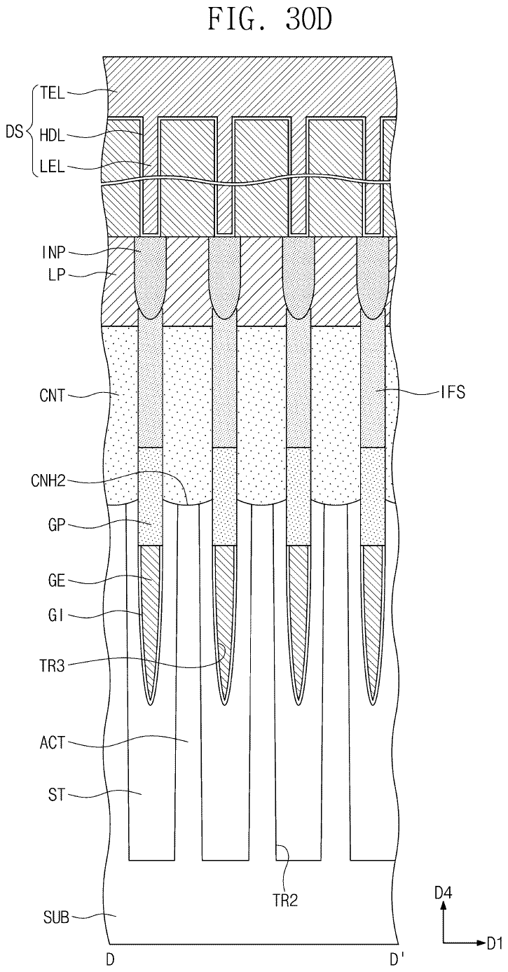

Referring to FIGS. 29 and 30A to 30D, landing pads LP may be correspondingly formed on the contacts CNT. For example, a metal layer may be formed on the contacts CNT and the dielectric fences IFS. The metal layer may be patterned to form a plurality of landing pads LP.

The patterning of the metal layer may be achieved by using a photolithography process discussed above with reference to FIGS. 4 to 14. The photomask 1400 discussed above with reference to FIG. 14 may be used as a photomask for forming the landing pads LP. For example, the photomask for forming the landing pads LP may be manufactured through an OPC method according to the present inventive concepts discussed above with reference to FIGS. 4 to 14.

Since the landing pads LP are formed by using a photomask achieved through an OPC method according to the present inventive concepts, the landing pads LP may be more accurately and more reliably formed despite their fine size and narrow pitch. Therefore, landing pads LP may be more accurately and more reliably formed on corresponding contacts CNT while preventing or reducing process failure.

A space between a plurality of landing pads LP may be filled with a dielectric material to form a dielectric pattern INP. First electrodes LEL may be correspondingly formed on the landing pads LP. A patterning process for forming the first electrodes LEL may use a photolithography process according to the present inventive concepts.

A dielectric layer HDL may be conformally formed on the first electrodes LEL. A second electrode TEL may be formed on the dielectric layer HDL. The first electrode LEL, the dielectric layer HDL, and the second electrode TEL may constitute a data storage element DS, for example, a capacitor. Although not shown, the second electrode TEL may be provided thereon with a plurality of stacked metal layers (e.g., M1, M2, M3, M4, and the like).

In an OPC method according to the present inventive concepts, a chemical reaction of a metal oxide resist (MOR) material may be used to obtain a model in consideration of characteristics of a photoresist layer PRL and a under layer. A chemical equation according to the present inventive concepts may include correction parameters, and the correction parameters may be corrected until a target error satisfies an allowable (or, alternatively, target, desirable, or determined) range. The chemical equation including the correction parameters may be employed to maintain consistency of OPC and also to improve accuracy and reliability of the OPC method of the MOR material. That is, more precise active patterns ACT, among other features, may be more reliably produced using the EUV lithography process according to some example embodiments. For example, according to some example embodiments, there may be an improvement in manufacturing of semiconductor devices and performance thereof based on the above methods. Therefore, the improved devices and methods overcome the deficiencies of the conventional devices and methods while reducing differences between aerial images and resist images, pattern distortion, resource consumption (e.g., based on fewer malformed devices), and/or improving process accuracy, and process and device reliability.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

Although some embodiments of the present inventive concepts have been discussed with reference to accompanying figures, it will be understood that various changes in form and details may be made therein without departing from the spirit and scope of the present inventive concepts. It therefore will be understood that the embodiments described above are just illustrative but not limitative in all aspects.

What is claimed is:

1. A semiconductor fabrication method, comprising:
forming a under layer and a photoresist layer on a substrate;
performing an optical proximity correction (OPC) on a layout to generate a corrected layout; and
using a photomask manufactured with the corrected layout to form a photoresist pattern on the under layer,
performing the OPC includes
generating a first function including a first correction parameter;
producing a resist image from the first function;
measuring a target error for the resist image; and
correcting the first correction parameter into a second correction parameter,
the first correction parameter and the second correction parameter include a certain number of hydrogen radicals that migrate from the under layer to the photoresist layer.

2. The method of claim 1, wherein the photoresist pattern comprises metal oxide.

3. The method of claim 1, wherein
the first function further comprises a process parameter, and
the process parameter comprises a thickness of the under layer.

4. The method of claim 1, wherein
forming the photoresist pattern comprises:
forming a photoresist layer on the under layer; and
irradiating light to the photoresist layer by using the photomask, and the light produces the hydrogen radicals in the under layer.

5. The method of claim 4, wherein a portion of the photoresist layer forms a cross-linking therein and condenses by the light to form a condensed portion.

6. The method of claim 5, wherein producing the resist image comprises calculating a ratio of a volume of the condensed portion of the photoresist layer to a volume of the photoresist layer.

7. The method of claim 6, wherein forming the photoresist pattern comprises removing a non-condensed portion of the photoresist layer.

8. The method of claim 1, wherein performing the OPC comprises correcting the second correction parameter until the target error satisfies a target range.

9. The method of claim 1, further comprising:
forming on the substrate a device isolation layer that defines an active pattern;
forming a gate electrode that extends across the active pattern;
forming a first source/drain region and a second source/drain region on an upper portion of the active pattern, the first source/drain region adjacent to one side of the gate electrode, and the second source/drain region adjacent to another side of the gate electrode;
forming a bit line electrically coupled to the first source/drain region;
forming a contact electrically coupled to the second source/drain region;
forming a metal layer on the contact;
patterning the metal layer to form a landing pad by using the photoresist pattern; and
forming a data storage element on the landing pad.

10. The method of claim 1, wherein an oxide layer is between the substrate and the under layer.

11. A semiconductor fabrication method, comprising:
forming an under layer and a photoresist layer on a substrate;
performing an optical proximity correction (OPC) on a layout to generate a corrected layout; and
using a photomask manufactured with the corrected layout to form a photoresist pattern from the photoresist layer,
performing the OPC includes
generating a first function including a first correction parameter;
producing a resist image from the first function; and
measuring a target error for the resist image,
forming the photoresist pattern includes using the photomask to irradiate light to the photoresist layer,
a first portion of the photoresist layer forms a cross-linking therein and condenses by the light, and
producing the resist image includes calculating a ratio of a volume of the first portion to a volume of the photoresist layer.

12. The method of claim 11, wherein the photoresist layer comprises metal oxide.

13. The method of claim 11, wherein performing the OPC further comprises:
determining whether the target error falls within a target range; and
correcting the first correction parameter into a second correction parameter,
wherein the first correction parameter and the second correction parameter comprise a certain number of hydrogen radicals that migrate from the under layer to the photoresist layer.

14. The method of claim 13, wherein performing the OPC further comprises correcting the second correction parameter until the target error satisfies the target range.

15. The method of claim 11, wherein forming the photoresist pattern comprises removing a remaining portion other than the first portion of the photoresist layer.

16. A semiconductor fabrication method, comprising:
performing an optical proximity correction on a layout to generate a corrected layout;
manufacturing a photomask with the corrected layout;
forming an under layer and a photoresist layer on a substrate; and
using the photomask to expose and develop the photoresist layer to form photoresist patterns,
performing the OPC includes
generating a first function including a first correction parameter and a process parameter;
producing a resist image from the first function;
measuring a target error for the resist image; and
correcting the first correction parameter into a second correction parameter,
the photoresist layer includes metal oxide, and
the process parameter includes a thickness of the under layer.

17. The method of claim 16, wherein forming the photoresist patterns comprises producing a hydrogen radical in the under layer by light.

18. The method of claim 16, wherein the first correction parameter and the second correction parameter comprise a certain number of hydrogen radicals that migrate from the under layer to the photoresist layer.

19. The method of claim 17, wherein a portion of the photoresist layer forms a cross-linking therein and condenses by the light to form a condensed portion.

20. The method of claim 19, wherein forming the photoresist patterns comprises removing a non-condensed portion of the photoresist layer.
